(19) United States
(12) Patent Application Publication
(10) Pub. No.: US 2013/0115453 A1
(43) Pub. Date: May 9, 2013

(54) HYBRID NANOSTRUCTURE, A METHOD FOR FORMING THE HYBRID NANOSTRUCTURE, AND AN ELECTRODE INCLUDING A PLURALITY OF THE HYBRID NANOSTRUCTURES

(71) Applicant: Nanyang Technological University, Singapore (SG)

(72) Inventors: Hongjin Fan, Singapore (SG); Jinping Liu, Singapore (SG); Cao Guan, Singapore (SG)

(73) Assignee: NANYANG TECHNOLOGICAL UNIVERSITY, Singapore (SG)

(21) Appl. No.: 13/666,444

(22) Filed: Nov. 1, 2012

Related U.S. Application Data
(60) Provisional application No. 61/555,121, filed on Nov. 3, 2011.

(51) Int. Cl. H05K 1/02; H05K 3/00

(52) U.S. Cl. CPC H05K 1/0213; H05K 3/00
USPC 428/372; 174/250; 205/111; 427/58; 427/122

(57) ABSTRACT

The present invention is directed to a hybrid nanostructure. The hybrid nanostructure includes at least two pseudocapacitative materials arranged in an elongate core-shell arrangement, wherein the core is an elongate nanostructure comprising or consisting of the first pseudocapacitative material and the shell is a plurality of flake- or sheet-like nanostructures attached to the core structure and comprising or consisting of the second pseudocapacitative material. The present invention also relates to a method for forming the hybrid nanostructure, and an electrode including a plurality of the hybrid nanostructures.

### CROSS-REFERENCE TO RELATED APPLICATION

This application claims the benefit of priority of U.S. provisional application No. 61/555,121, filed 3 Nov. 2011, the content of it being hereby incorporated by reference in its entirety for all purposes.

### TECHNICAL FIELD

Various embodiments relate to a hybrid nanostructure, a method for forming the hybrid nanostructure, and an electrode including a plurality of the hybrid nanostructures. Various embodiments further relate to an electrode including a plurality of flake- or sheet-like nanostructures extending from a surface of a substrate, and a method for forming the electrode.

### BACKGROUND

With an ever-increasing power and energy needs in applications from next-generation plug-in hybrid electric vehicles (PHEVs) and modern consumer electronics to micro/nanoelectromechanical systems, more recent research and development have focused on new electrode materials for advanced energy-storage devices such as batteries and pseudocapacitors (also called electrochemical capacitors, or supercapacitors). Pseudocapacitors have a number of desirable properties, including fast charging-discharging, long cycle life and the ability to deliver up to ten times more power than conventional batteries. In addition, pseudocapacitors play an important role in complementing fuel cells in future all-electric vehicles based on clean and renewable energy media.

There are three major types of electrode materials for pseudocapacitors, including carbonaceous materials, metal oxides/hydroxides, and conducting polymers. Carbon-based materials store charge electrostatically from the reversible adsorption of ions onto their surfaces, leading to high power delivery at the cost of low energy density. Carbon-based electrodes may store energy densities measured in specific capacitance (Cₛₚ) on the order of about 150 F/g, capacitance per unit area (Cₐ) of about 20 μF/cm² and capacitance per unit volume (Cᵥ) of about 100 F/cm³. It is very challenging to further increase the specific and volumetric capacitances of such carbon-based electrodes due to the difficulties in controlling the pore size, electrochemically active surface area, and surface chemistry of carbon. Metal oxides/hydroxides and conducting polymers store charge in a faradaic or redox-type process similar to batteries, which enables high energy density but is in general kinetically unfavorable due to the relatively low electrical conductivity of metal oxides leading to low power density.

To bridge the performance gap between these materials, attempts on electrode design have been extensively made. Despite a huge number of developments, nearly all of them can be classified into one general concept, that is, the use of “pseudocapacitive material-conductive matrix” hybrid nanostructures. In this regard, materials with high pseudocapacitance (e.g. metal oxides) are incorporated directly into highly-conductive nanostructured carbons (carbon nanotubes, mesoporous carbons, carbon aerogels, graphene, etc.) or conducting polymers, with the different components contacting either at the nanoscale or microscale. By combining unique properties of individual constituents, improved performance has been demonstrated in such electrodes. However, while relatively low weight fraction of pseudocapacitive material is generally considered to achieve better rate and cycling performance; energy density in most cases is sacrificed.

Some other efforts have been directed to hybrid pseudocapacitive materials such as mixed metal oxides and binary metal oxide/hydroxides. However, due to the lack of well-defined micro-/nanostructures, electrochemical performance for this kind of electrode material has been largely unsatisfactory and the possible synergistic effect between individual constituents has not been well understood so far.

There is therefore need for integrated electrode architectures and methods for forming these architectures, in which the structural features and electroactivities of each component in the integrated electrode architecture are substantially manifested, the interface/chemical distributions are homogeneous at a nanoscale level, and a fast ion and electron transfer.

### SUMMARY

In a first aspect of the invention, a hybrid nanostructure is provided. The hybrid nanostructure includes at least two pseudocapacitative materials arranged in an elongate core-shell arrangement, wherein the core is an elongate nanostructure comprising or consisting of the first pseudocapacitative material and the shell is a plurality of flake- or sheet-like nanostructures attached to the core structure and comprising or consisting of the second pseudocapacitative material.

In a second aspect of the invention, an electrode is provided. The electrode includes a substrate, and a plurality of spaced apart hybrid nanostructures as described above extending from a surface of the substrate.

In a third aspect of the invention, a method for forming a hybrid nanostructure as described above is provided. The method includes providing a substrate, forming a plurality of spaced apart elongate nanostructures comprising or consisting of the first pseudocapacitative material extending from a surface of the substrate, and forming a plurality of flake- or sheet-like nanostructures comprising or consisting of the second pseudocapacitative material on the surface of each elongate nanostructure.

In a fourth aspect of the invention, an electrode is provided. The electrode includes a substrate, and a plurality of flake- or sheet-like nanostructures comprising or consisting of at least one pseudocapacitative material extending from a surface of the substrate.

In a fifth aspect of the invention, a method for forming an electrode as described above is provided. The method includes providing a substrate, and forming a plurality of flake- or sheet-like nanostructures comprising or consisting of a pseudocapacitative material extending from a surface of the substrate.

### BRIEF DESCRIPTION OF THE DRAWINGS

In the drawings, like reference characters generally refer to like parts throughout the different views. The drawings are not necessarily to scale, emphasis instead generally being placed upon illustrating the principles of the invention. In the following description, various embodiments of the invention are described with reference to the following drawings, in which:

FIG. 1A shows a flow chart illustrating a method for forming a hybrid nanostructure, according to various embodiments.

FIG. 1B shows a flow chart illustrating a method for forming an electrode, according to various embodiments.

FIG. 2A shows a schematic diagram illustrating the process for fabricating flake-like nanostructures on nanowires via an interfacial reactive template method, according to various embodiments.

FIG. 2B shows the Raman spectra of the Co₃O₄@MnO₂ hybrid nanostructure array obtained at different growth stages.

FIG. 2C shows the X-ray diffraction (XRD) pattern of the 5-hour grown Co₃O₄@MnO₂ hybrid nanostructure array.

FIG. 2D shows an energy-dispersive X-ray spectrometry (EDS) spectrum of the Co₃O₄@MnO₂ hybrid nanostructure array.

FIG. 2E shows a plot of cyclic voltammograms (CVs) of the Co₃O₄@MnO₂ hybrid nanostructure array after 5 hours of growth, at different scan rates.

FIG. 2F shows a plot of cyclic voltammogram (CV) of the Co₃O₄@MnO₂ hybrid nanostructure array, after 2 hours of growth, at a scan rate of 50 mVs⁻¹.

FIG. 2G shows a plot of charge/discharge curves for a 5-hour-grown Co₃O₄@MnO₂ hybrid nanostructure array.

FIG. 2H shows a plot of current density dependence of the areal capacitance and specific capacitance of both the Co₃O₄@MnO₂ hybrid nanostructure array and the Co₃O₄ nanowire array.

FIG. 2I shows a plot of cycling performance of both the Co₃O₄@MnO₂ hybrid nanostructure and pristine Co₃O₄ nanowire arrays (5000 cycles). The inset shows the charge-discharge curves of the last 15 cycles for the Co₃O₄@MnO₂ hybrid nanostructure array.

FIG. 2J shows a schematic diagram illustrating the charge storage of the Co₃O₄@MnO₂ hybrid nanostructure array, where both the Co₃O₄ core and the MnO₂ shell materials contribute to the charge storage.

FIG. 2K shows a plot of cycling stability of the Co₃O₄@MnO₂ hybrid nanostructure array at progressively varied current density.

FIG. 3A shows energy-dispersive X-ray spectrometry (EDS) spectra of the CoO@NiHON hybrid nanostructure array.

FIG. 3B shows the X-ray diffraction (XRD) pattern of the arrays of CoO@NiHON hybrid nanostructures and CoO nanowires on the nickel foam.

FIG. 3C shows the Fourier transform infrared (FTIR) spectrum of the array of CoO@NiHON hybrid nanostructures.

FIG. 3D shows a plot of cyclic voltammograms (CVs) of the CoO@NiHON hybrid nanostructure array on nickel foam, at different scan rates.

FIG. 3E shows a plot of cyclic voltammogram (CV) of the CoO@NiHON hybrid nanostructure array on nickel foam at a scan rate of 40 mVs⁻¹.

FIG. 3F shows a plot of charge/discharge curves for the CoO@NiHON hybrid nanostructure array on nickel foam at different current densities.

FIG. 3G shows a plot of charge/discharge curves for the hybrid CoO@NiHON nanostructure array and CoO nanowires on nickel foams at the areal charge-discharge current of 10 mA cm⁻².

FIG. 3H shows a plot of cycling performance of both the CoO@NiHON hybrid nanostructures and pristine CoO nanowires arrays (2000 cycles).

FIG. 3I shows a plot of the charge/discharge curves of the last 10 cycles for the array of CoO@NiHON hybrid nanostructures.

FIG. 3J shows a plot of cycling stability of the CoO@NiHON hybrid nanostructures array at progressively varied current density.

FIG. 4A shows the X-ray diffraction (XRD) patterns showing the transformation of Co(OH)₂ to CoO after thermal annealing.

FIG. 4B shows the Fourier transform infrared (FTIR) spectra showing the transformation of Co(OH)₂ to CoO after thermal annealing.

FIG. 4C shows a plot of cyclic voltammogram (CV) of the CoO nanowalls on nickel foam at a scan rate of 2 mVs⁻¹.

FIG. 4D shows a plot of charge/discharge curves for the CoO nanowalls at different current densities.

FIG. 4E shows a plot of cycling performance of the CoO nanowalls (5000 cycles). The inset shows the XRD patterns before cycling and after 5000 cycles.

FIG. 4F shows the X-ray diffraction (XRD) patterns of the Ni(OH)₂ material electrodeposited on the CoO nanowalls and on bare nickel foam.

FIG. 4G shows a plot of the specific capacitance (in two units) of the CoO@Ni(OH)₂ hybrid nanostructure as a function of the Ni(OH)₂ electrodeposition time.

FIG. 4H shows a plot of cyclic voltammograms (CVs) of the CoO nanowall electrode and the CoO@Ni(OH)₂ hybrid electrode at the same current density at a scan rate of 2 mVs¹.

FIG. 4I shows a plot of areal capacitance of the three structures Ni(OH)₂, CoO, and CoO@Ni(OH)₂ as a function of current densities.

FIG. 4J shows a plot of cyclic performances of different types of nanostructured supercapacitor electrodes.

FIG. 5A shows the X-ray diffraction (XRD) pattern of the of the ZnO@MnO₂ array after the first interfacial reaction (Step 1).

FIG. 5B shows the Raman spectrum of the ZnO@MnO₂ nanostructure array after the first interfacial reaction (Step 1).

FIG. 5C shows the X-ray photoelectron spectroscopy (XPS) spectrum of the ZnO@MnO₂ hybrid nanostructure array.

FIG. 5D shows the Raman spectrum of the MnO₂@NiO hybrid nanostructure array after the second interfacial reaction (Step 2).

FIG. 5E shows energy-dispersive X-ray spectrometry (EDS) spectra of the MnO₂@NiO hybrid nanostructure array.

FIG. 5F shows a plot of cyclic voltammograms (CVs) of the MnO₂@NiO and MnO₂ tubular arrays at a scan rate of 50 mVs⁻¹.

FIG. 5G shows a plot of charge/discharge curves of the first cycle at a current density of 8.5 mA cm⁻² for the MnO₂@NiO and MnO₂ tubular arrays.

FIG. 5H shows a plot of cycling performance of the MnO₂@NiO and MnO₂ tubular arrays at a current density of 8.5 mA cm⁻².

FIG. 5I shows a plot of discharge curves for the MnO₂@NiO tubular array at different current densities.

FIG. 5J shows a plot of rate capability and energy density as a function of current density for the MnO₂@NiO tubular array.

FIG. 5K shows a plot of cycling performance of the MnO₂@NiO tubular array at a current density of 15 mA cm⁻².

FIG. 5L shows a plot of the charge/discharge curves of the last 20 cycles for the MnO₂@NiO tubular array.

FIG. 6 shows a schematic perspective view of a pseudocapacitor cell, according to various embodiments.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments described in the context of one of the methods or devices may be analogously valid for the other method or device. Similarly, embodiments described in the context of a method may be analogously valid for a device, and vice versa.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element includes a reference to one or more of the features or elements.

In the context of various embodiments, the phrase “at least substantially” may include “exactly” and a reasonable variance.

In the context of various embodiments, the term “about” or “approximately” as applied to a numeric value encompasses the exact value and a reasonable variance.

As used herein, the term “and/or” includes any and all combinations of one or more of the associated listed items.

Various embodiments relate to the fabrication and integration of one or more high-capacitance metal oxides and/or metal hydroxides which are in nanoscale dimensions and structures as pseudocapacitative materials for high-capacitance pseudocapacitor electrodes, for example for supercapacitor applications.

Various embodiments may provide metal oxide nanostructure(s) and/or metal hydroxide nanostructure(s) or hybrid nanostructure(s), and electrodes or pseudocapacitor electrodes incorporating one or more of these nanostructures, for pseudocapacitive energy storage applications. In various embodiments, transition metal (e.g. Mn, Fe, Co, Ni, Ru, etc.) oxides and hydroxides are suitable for supercapacitor applications because of their variety of oxidation states for charge transfer and high mass densities. Transition metal oxides/hydroxides store charges with surface faradaic (redox) reactions, which enable higher energy density as compared to, for example carbon. Nanotechnology may enhance their redox kinetics which may be limited by the physical changes during charge/discharge (for example caused by ion diffusion and electron transfer), and therefore nanosized transition metal oxides and hydroxides may achieve high specific capacitances (SCs, or Cₛₚ). In addition, porous nanostructures may reduce ionic and electronic diffusion distance and provide large electrode/electrolyte contact areas.

Various embodiments may provide metal oxide nanomaterials and/or metal hydroxide nanomaterials, and methods for forming the metal oxide nanomaterials and/or the metal hydroxide nanomaterials, where these nanomaterials may be integrated into a single electrode or electrode arrangement for pseudocapacitive energy storage devices. The methods of various embodiments may be carried out without using blenders. Various embodiments may include approaches for materials selection, fabrication procedure, nanostructure design and electrode construction, electrolyte selection, and electrochemical performance of the electrodes made from the integrated metal oxide/hydroxide nanostructures. In various embodiments, the pseudocapacitive materials for the nanomaterials or nanostructures may include, but not limited to, cobalt oxide (e.g. CoO and/or Co₃O₄), manganese oxide (e.g. MnO₂), nickel oxide (e.g. NiO), nickel hydroxide (e.g. Ni(OH)₂), and nickel hydroxidenitrate (Ni₃(OH)₄(NO₃)₂; NiHON). These materials may provide high specific capacitance. In various embodiments, the nanostructures may include, but not limited to, porous nanowires, porous nanoflakes, porous nanowalls and thin membranes.

Various embodiments may provide metal oxide/hydroxide nanostructure electrode designs/arrangements/architectures that integrate pseudocapacitive materials into or onto a single elongate nanostructure (e.g. a nanowire or nanotube) and align the nanostructure or plurality of such nanostructures directly on a current collector substrate, without any binder or conductive additives. In various embodiments, high crystalline quality nanowires have a direct contact with the current collector, which may allow quick electron transport. In contrast, additives employed in conventional pseudocapacitor electrodes introduce additional interfaces in the electrode matrix, which adversely affect the electron transport. Various embodiments may also provide metal oxide/hydroxide nanostructure electrode architectures that integrate pseudocapacitive materials directly on a current collector substrate.

The structural features and electroactivities of each component of each pseudocapacitor electrode of various embodiments may be fully manifested, and the interface/chemical distributions may be homogenous at a nanoscale level. In addition, the pseudocapacitor electrodes of various embodiments may provide a fast ion and electron transfer. As a result, the hybrid or integrated electrodes of various embodiments may provide high specific capacitance without sacrificing rate capability and cycle life, even in the absence of any carbon or polymer-based conducting media. However, it should be appreciated that such carbon or polymer-based conductiive materials may also be incorporated in the electrodes to further enhance the performances of the electrodes of various embodiments.

In various embodiments, integrating two or more active materials with high redox electroactivity into one ordered nanostructure may increase the areal capacitance (Cₐ). In such a configuration, more space in the electrode films may be efficiently used to store energy, with synergistic effect between the active materials. By having an ordered array architecture, the Cₐ may be increased without substantially sacrificing cycle life and rate performance.

The electrodes of various embodiments, incorporating the nanostructures or hybrid nanostructures as will be described later, may provide high capacitance, as compared to conventional carbon-based electrodes, for example in terms of the areal and volumetric capacitances, which may lead to exceptionally high energy density. The electrodes of various embodiments may exhibit gravimetric, areal, and volumetric capacitances of about 800 F/g, about 0.4 F/cm² and 1000 F/cm³, respectively. The areal capacitance is several orders of magnitude higher than the conventional carbon-based electrodes (˜100 F/g, ˜10-20 μF/cm², 100 F/cm³), carbon nanotube-based electrodes (˜150-300 F/g, ˜10-40 μF/cm², 150 F/cm³), and graphene electrodes (˜100-400 F/g, 10-30 μF/cm², 100-200 F/cm³).

The synthesis methods of various embodiments are based on hydrothermal, electrodeposition, and annealing processes, which are simple, facile and easy to scale up on various flexible current collectors (e.g. stainless steel foil, commercial Ni foam). Large-scale electrode fabrication may be readily realized by using large foils, high amounts of precursors and large-volume containers (e.g. commercially available autoclaves).

Various embodiments may provide an approach that provides large amount of energy in a small device size. The electrodes of various embodiments may be employed in various applications, including consumer electronics devices which may require shorter charging time and storage of high energy in a limited volume, as well as the capability for charging and discharging numerous times. The devices may include but not limited to next-generation cell phones and digital cameras. Other applications may include full power-assisted hybrid electrical vehicles, grid storage (e.g. wind turbines), transportation sectors and other large-scale applications for supercapacitor technology.

Various embodiments may provide a hybrid nanostructure including at least two pseudocapacitative materials arranged in an elongate core-shell arrangement, wherein the core is an elongate nanostructure comprising or consisting of the first pseudocapacitative material and the shell is a plurality of flake- or sheet-like nanostructures attached to the core structure and comprising or consisting of the second pseudocapacitative material.

In other words, the hybrid nanostructure includes a core structure, in the form of an elongate nanostructure, of a first pseudocapacitative material, and a shell, in the form of a plurality of flake- or sheet-like nanostructures, of a second pseudocapacitative material, attached to the core structure, so as to form an elongate core-shell arrangement.

In various embodiments, the plurality of flake- or sheet-like nanostructures may be attached to the core structure in the form of “branches” extending or projecting outwardly from a periphery or a surface of the core structure. In this arrangement, each elongate nanostructure may be considered as a “stem” with the flake- or sheet-like nanostructures as “leaves” branching from the stem.

In the context of various embodiments, the term “elongate” as applied to a nanostructure may mean a nanostructure that extends preferentially in one direction, longitudinally.

In the context of various embodiments, the term “elongate nanostructure” may include a nanowire, a nanotube, a nanocolumn or a nanopillar.

In various embodiments, the first pseudocapacitative material comprises or consists of a transition metal oxide or a transition metal hydroxide. The first pseudocapacitative material may include or may be cobalt oxide (e.g. CoO, Co₃O₄), nickel oxide (NiO), zinc oxide (ZnO), tin oxide (SnO₂) or any combination thereof.

In various embodiments, the second pseudocapacitative material comprises or consists of a transition metal oxide or a transition metal hydroxide. The second pseudocapacitative material may include or may be any one of manganese oxide (MnO₂), cobalt oxide (CoO), nickel oxide (NiO) or nickel hydroxidenitrate (NiHON).

In various embodiments, the elongate nanostructure may be porous, thereby providing an increased surface area.

In various embodiments, the elongate nanostructure may have a diameter of between about 50 nm and about 100 nm, for example between about 50 nm and about 80 nm, between about 70 nm and about 100 nm, or between about 60 nm and about 80 nm.

In various embodiments, the elongate nanostructure may have a length of between about 1 μm and about 10 μm, for example between about 1 μm and about 8 μm, between about 1 μm and about 5 μm, between about 4 μm and about 10 μm, or between about 4 μm and about 6 μm.

In various embodiments, the elongate nanostructure may have a cross sectional shape, defined along a transverse axis perpendicular to the longitudinal axis of the elogate nanostructure, that is a square or a rectangle or a circle or an ellipse or a triangle or a hexagon or an octagon.

In various embodiments, each flake- or sheet-like nanostructure may be porous, thereby providing an increased surface area, which may contribute to a much higher specific capacitance as compared to solid flakes. Each flake- or sheet-like nanostructure may have pores of a diameter of between about 10 nm and about 100 nm, for example between about 10 nm and about 50 nm, between about 10 nm and about 20 nm, between about 20 nm and about 80 nm, or between about 20 nm and about 50 nm.

In various embodiments, each flake- or sheet-like nanostructure may have thickness of between about 1 nm and about 10 nm, for example between about 1 nm and about 5 nm, between about 1 nm and about 3 nm, between about 3 nm and about 10 nm, or between about 3 nm and about 5 nm.

In various embodiments, each flake- or sheet-like nanostructure may extend between about 10 nm and about 100 nm from a surface of the elongate nanostructure, for example between about 10 nm and about 50 nm, between about 10 nm and about 20 nm, between about 20 nm and about 80 nm, or between about 20 nm and about 50 nm.

In various embodiments, the plurality of flake- or sheet-like nanostructures may be cross-linked, for example inter-linked or inter-connected with each other, via a portion of each flake- or sheet-like nanostructure.

In various embodiments, at least a portion of each flake- or sheet-like nanostructure may be spaced apart relative to an adjacent flake- or sheet-like nanostructure, thereby forming gaps or voids between adjacent flake- or sheet-like nanostructures.

Various embodiments may provide an electrode including a substrate, and a plurality of spaced apart hybrid nanostructures, as described above, extending from a surface of the substrate. In other words, each hybrid nanostructure has a proximal end formed on the substrate, and an end distal to the substrate which is a free end. Adjacent hybrid nanostructures may be spaced apart, for example by a spacing or distance or gap, s, of between about 10 nm and about 100 nm, for example between about 10 nm and about 50 nm, between about 10 nm and about 20 nm, between about 20 nm and about 100 nm, between about 20 nm and about 50 nm, or between about 40 nm and about 50 nm.

In various embodiments, the plurality of spaced apart hybrid nanostructures may be arranged in direct contact with the surface of the substrate.

In various embodiments, the plurality of hybrid nanostructures may be arranged at least substantially vertically or perpendicularly to the surface of the substrate. However, it should be appreciated that any one or more or all of the plurality of hybrid nanostructures may be arranged slightly angled to the surface of the substrate, for example about 1° to 10° from an axis defined perpendicularly to the surface.

In various embodiments, the surface of the substrate may include or may be a porous surface. In various embodiments, the substrate may be a porous substrate.

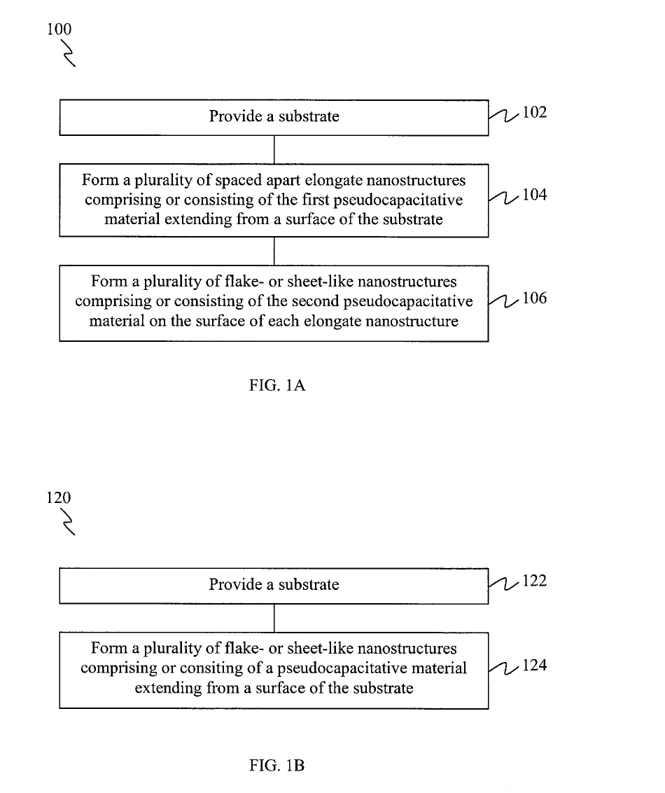

FIG. 1A shows a flow chart illustrating a method 100 for forming the hybrid nanostructure as described above, according to various embodiments.

At 102, a substrate is provided.

At 104, a plurality of spaced apart elongate nanostructures comprising or consisting of the first pseudocapacitative material are formed extending from a surface of the substrate.

At 106, a plurality of flake- or sheet-like nanostructures comprising or consisting of the second pseudocapacitative material are formed on the surface of each elongate nanostructure.

In various embodiments, at 106, an interfacial reactive template layer is formed on the surface of each elongate nanostructure and the template layer is reacted with a precursor of the second pseudocapacitative material to form the plurality of flake- or sheet-like nanostructures on the surface of each elongate nanostructure.

In various embodiments, in order to form the interfacial reactive template layer, at least a portion of each elongate nanostructure is immersed in an aqueous glucose solution, and thereafter, the elongate nanostructure is subjected to a carbonization process.

In various embodiments, the interfacial reactive template layer may be a coating on the surface of each elongate nanostructure, the coating having a thickness of between about 2 nm and about 10 nm, for example between about 2 nm and about 5 nm, between about 2 nm and about 3 nm, or between about 4 nm and about 10 nm.

In various embodiments of the method 100, the second pseudocapacitative material comprises or consists of manganese oxide (MnO₂).

In various embodiments, the plurality of elongate nanostructures may be formed by means of a hydrothermal process or an electrodeposition process or a chemical vapour deposition process.

Various embodiments may further provide an electrode including a substrate, and a plurality of flake- or sheet-like nanostructures comprising or consisting of at least one pseudocapacitative material extending from a surface of the substrate. The plurality of flake- or sheet-like nanostructures may extend at least substantially vertically or perpendicularly to the surface of the substrate. However, it should be appreciated that any one or more or all of the flake- or sheet-like nanostructures may extend slightly angled to the surface of the substrate, for example about 1° to 10° from an axis defined perpendicularly to the surface.

In various embodiments, the pseudocapacitative material comprises or consists of a transition metal oxide or a transition metal hydroxide. The pseudocapacitative material may include or may be cobalt oxide (CoO) or nickel oxide (NiO).

In various embodiments, the plurality of flake- or sheet-like nanostructures may be arranged in direct contact with the surface of the substrate.

In various embodiments, the surface of the substrate may include or may be a porous surface. In various embodiments, the substrate may be a porous substrate. In various embodiments, the substrate may be a metal substrate In one embodiment, the substrate may be a porous nickel (Ni) foam or substrate.

In various embodiments, each flake- or sheet-like nanostructure may be porous, thereby providing an increased surface area, which may contribute to a much higher specific capacitance as compared to solid flakes. Each flake- or sheet-like nanostructure may have pores of a diameter of between about 10 nm and about 100 nm, for example between about 10 nm and about 50 nm, between about 10 nm and about 20 nm, between about 20 nm and about 80 nm, or between about 20 nm and about 50 nm.

In various embodiments, each flake- or sheet-like nanostructure may have thickness of between about 1 nm and about 10 nm, for example between about 1 nm and about 5 nm, between about 1 nm and about 3 nm, between about 3 nm and about 10 nm, or between about 3 nm and about 5 nm.

In various embodiments, each flake- or sheet-like nanostructure may extend between about 10 nm and about 100 nm from the surface of the substrate, for example between about 10 nm and about 50 nm, between about 10 nm and about 20 nm, between about 20 nm and about 80 nm, or between about 20 nm and about 50 nm.

In various embodiments, the plurality of flake- or sheet-like nanostructures may be cross-linked, for example inter-linked or inter-connected with each other, via a portion of each flake- or sheet-like nanostructure.

In various embodiments, at least a portion of each flake- or sheet-like nanostructure may be spaced apart relative to an adjacent flake- or sheet-like nanostructure, thereby forming gaps or voids between adjacent flake- or sheet-like nanostructures. In various embodiments, the spacing may be at least about 50 nm, for example between about 50 nm and about 200 nm, e.g. about 50 nm, about 80 nm, about 100 nm, about 150 nm, or about 200 nm.

In various embodiments, each flake- or sheet-like nanostructure further includes a second pseudocapacitative material. The second pseudocapacitative material comprises or consists of a transition metal oxide or a transition metal hydroxide. The second pseudocapacitative material may include or may be manganese oxide (MnO₂) or nickel hydroxide (Ni(OH)₂) or cobalt hydroxide (Co(OH)₂).

In various embodiments, each flake- or sheet-like nanostructure includes a coating comprising or consisting of the second pseudocapacitative material on a surface of each flake-like nanostructure.

FIG. 1B shows a flow chart illustrating a method 120 for forming an electrode, according to various embodiments.

At 122, a substrate is provided.

At 124, a plurality of flake- or sheet-like nanostructures comprising or consisting of a pseudocapacitative material are formed extending from a surface of the substrate.

In various embodiments, the plurality of flake- or sheet-like nanostructures may be formed by means of a hydrothermal process.

In various embodiments of the method 120, a coating comprising or consisting of a second pseudocapacitative material may be formed on a surface of each flake- or sheet-like nanostructure.

In various embodiments, the coating may be formed by means of an electrodeposition process.

In the context of various embodiments, the term “nanostructure” may have a size in at least one dimension in the nanometer (nm) range, for example, a range between about 1 nm and about 800 nm, for example between about 1 nm and about 500 nm, between about 1 nm and about 200 nm, between about 1 nm and about 100 nm, a range between 10 nm and 800 nm, between about 10 nm and about 200 nm or a range between 100 nm and 500 nm.

In the context of various embodiments, the substrate functions as a current collector.

In the context of various embodiments, the term “flake- or sheet-like nanostructure” may include nanoflakes, nanosheets or nanowalls. The term “flake- or sheet-like nanostructure” may also include a nanostructure having a small dimension in terms of its thickness.

In the context of various embodiments, a reference to a “flake-like nanostructure” includes a reference to a “sheet-like nanostructure”.

In the context of various embodiments, the term “metal oxide/hydroxide” may include metal oxide or metal hydroxide or a combination of metal oxide and metal hydroxide. Therefore, a reference to metal oxide/hydroxide nanostructures may include a reference to metal oxide nanostructures or metal hydroxide nanostructures or both metal oxide nanostructures and metal hydroxide nanostructures.

The electrodes and the methods for forming the electrodes, and the associated results will now be described by way of the following non-limiting embodiments and examples.

Flake-Like Nanostructures on Nanowires

Various embodiments may provide an electrode including an array of core-shell nanostructures having ultrathin metal oxide/hydroxide flake-like nanostructures (e.g. nanosheets), as shells, on metal oxide/hydroxide nanowires (e.g. MOₓ, M=Co, Zn, Sn), as cores. In one embodiment, the electrode may include an array of core-shell nanostructures having ultrathin manganese oxide (MnO₂) flake-like nanostructures on cobalt oxide (Co₃O₄) nanowires (termed Co₃O₄@MnO₂). The MnO₂ and Co₃O₄ nanostructures may be employed as active electrode materials. MnO₂ is suitable for pseudocapacitors or electrochemical capacitors applications due to its low cost, low toxicity, and natural abundance. The flake-like nanostructures may additionally or alternatively include ruthenium oxide (RuO₂) which provides extremely high specific capacitance of more than 700 F/g. Co₃O₄ is a suitable supercapacitor electrode material because of its high redox activity and great reversibility.

Such an electrode design may have one or more of the following advantages: (1) Both the core and shell materials are good pseudocapacitive metal oxides. (2) The nanostructured core and shell may have redox reactions with anions and cations from the electrolyte, respectively, both contributing to the electrochemical charge storage. (3) The shell, which may be porous, does not prohibit ion penetration into the core region. (4) The core material is of high crystalline quality and has a direct contact to the current collector, when formed directly on the current collector substrate, to enable quick electron transport. (5) The hybrid nanostructures may be well separated and immobilized to the substrate, avoiding the use of polymer binder and conductive additives and substantially reducing the “dead volume” in electrode materials. In various embodiments, the desired functions of each constituent may be effectively utilized, and additionally a strong synergistic effect may be realized.

In various embodiments, the three-dimensional (3D) interfacial templating method may achieve nanostructured electrodes in which the active materials (metal oxides) are integrated into a single core-shell structure. Such an electrode configuration may lead to electrochemical energy storage in both the core and shell materials, where the electrode employs the single-crystalline core material as the direct electron transport path, and the shell materials to maintain the core's stability during harsh redox reactions. An electrode having a high specific capacitance may be achieved, while maintaining long cycling lifetime and good rate performance.

The 3D interfacial template method for fabrication of the shell materials homogenously onto the surface of the pre-grown core nanostructure arrays may enable the use of only one precursor for the shell coating, and which is more facile, easier to manipulate, and requires a lower energy consumption compared to conventional electrochemical and physical deposition methods.

Generally, the synthesis of the array of integrated or hybrid core-shell nanostructures may be carried out as follows, via a two-step process: First, an array of core nanostructures (e.g. elongate nanostructures, e.g. nanowires) may be fabricated directly on a current collector substrate (e.g. stainless steel substrate, commercial Ni foam, etc.) by a hydrothermal method or electrodeposition or other suitable methods. Then, the shell materials or nanostructures may be deposited onto the surface or periphery of core nanotructures by a 3D interfacial chemical reaction (e.g. direct nucleation and growth) or by templating growth. For the templating growth method, a thin layer of interfacial reactive template (e.g. a carbon template) may be pre-coated on the array of core nanostructures. The shell material may be subsequently deposited, by means of a solution-based method, via a reaction of the precursor of the shell material with the template layer, which consumes the template layer. After complete reaction, the reactive template is absent as it has been in-situ removed as a result of the reaction with the precursor of the shell material to form the shell materials on the core nanostructures.

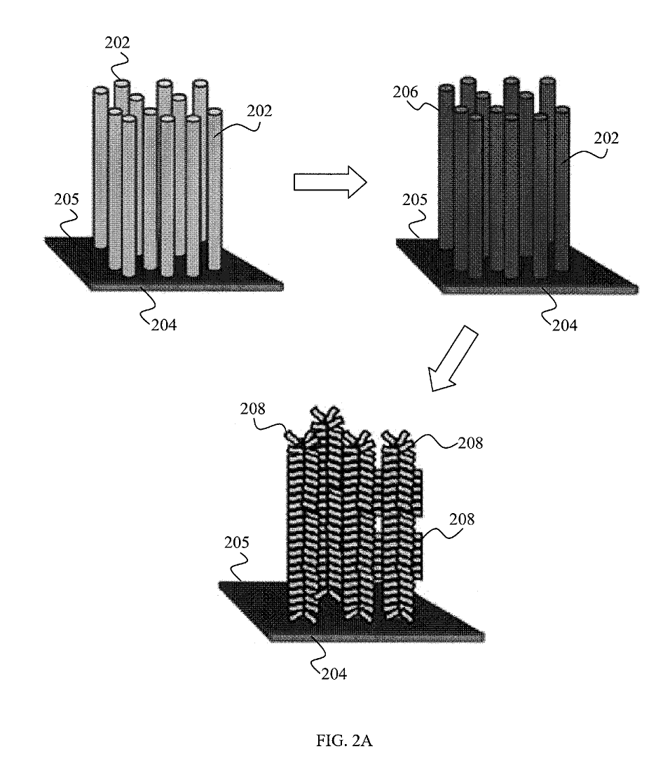

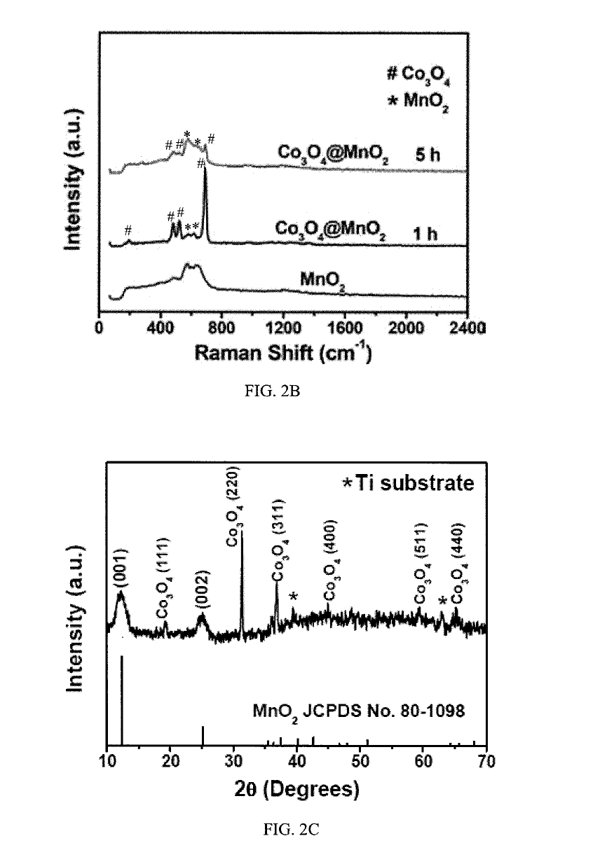

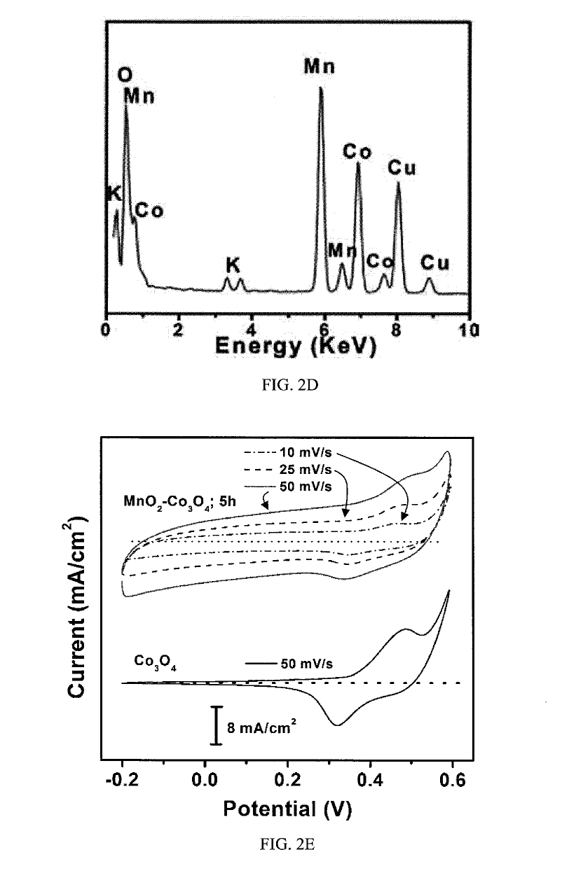

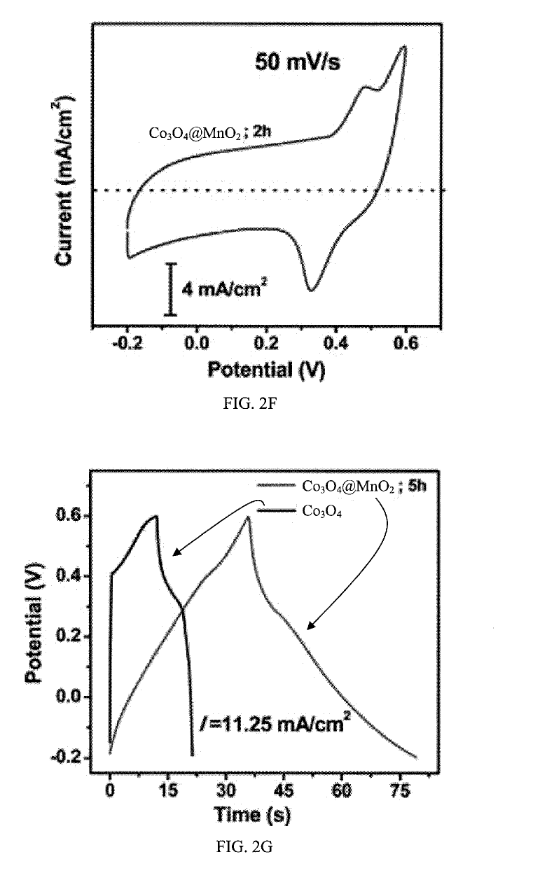

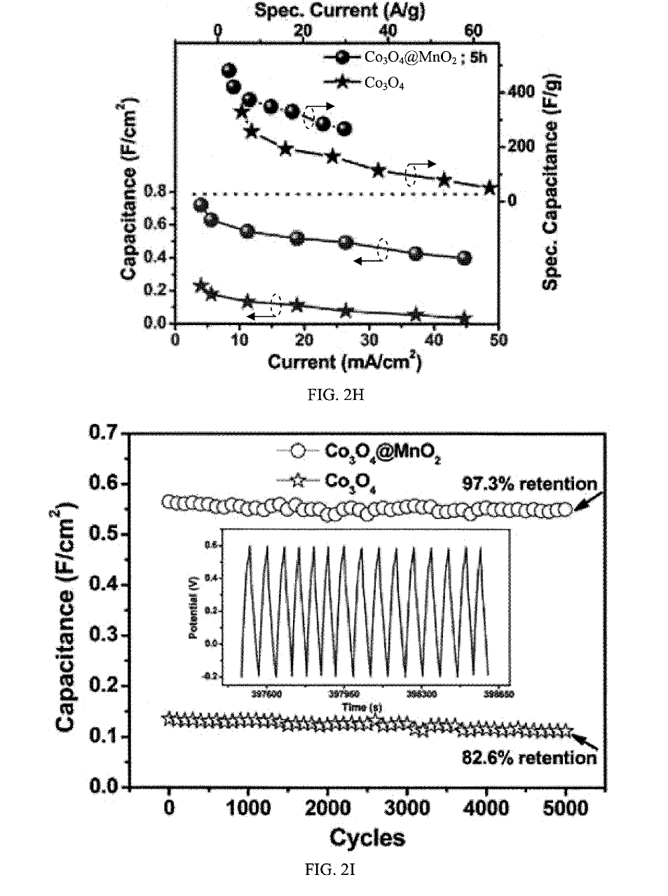

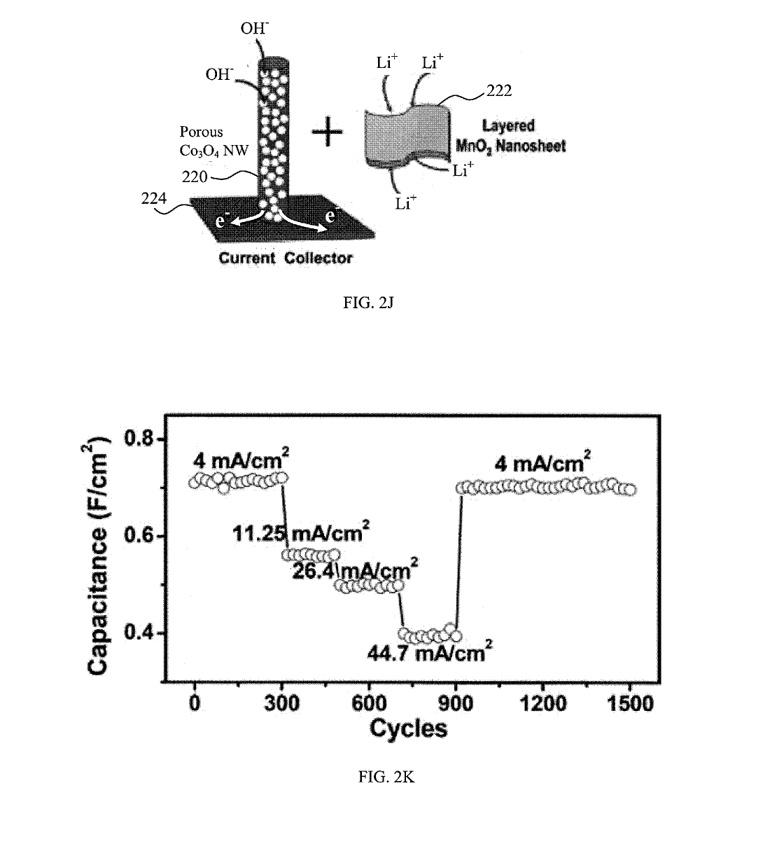

FIG. 2A shows a schematic diagram illustrating the process for fabricating flake-like nanostructures (e.g. MnO₂ flake-like nanostructures) on elongate nanostructures (e.g. nanowires, e.g. Co₃O₄ nanowires) via an interfacial reactive template method, according to various embodiments. Using Co₃O₄@MnO₂ hybrid nanostructures as a non-limiting example, an array of Co₃O₄ nanowires 202 may be grown on a substrate (e.g. a stainless steel substrate) 204 via a facile hydrothermal process. The array of Co₃O₄ nanowires 202 may be formed directly on the substrate 204, in contact with a surface 205 of the substrate 204, so as to enable fast electron transport.

The Co₃O₄ nanowires 202 may then be coated, at least substantially uniformly, with a carbon layer (e.g. an amorphous carbon layer) 206, by impregnation of the nanowires 202 via a glucose aqueous solution and a subsequent post-annealing process performed in argon (Ar) gas. The post-annealing process subjects the nanowires 202, after being impregnated with the glucose aqueous solution, to a carbonization process to form a uniform carbon coating 206 on the surface or periphery of the nanowires 202. However, it should be appreciated that other forms and/or structures of carbon may be employed, for example graphitic carbon such as carbon nanotubes and graphene.

The carbon layer 206 on the Co₃O₄ nanowires 202 is a sacrificial template, acting as an interfacial reactive template layer for growing the MnO₂ flake-like nanostructures, based on the green redox reaction between carbon (C) (e.g. amorphous carbon, graphitic carbons such as carbon nanotube and graphene) and potassium permanganate (KMnO₄), in the absence of any strong acid or alkali even at room temperature, according to the reaction (3C+4MnO₄⁻+H₂O=4MnO₂+CO₃²⁻+2HCO₃⁻), thereby producing MnO₂ nanostructures 208 with a well-defined morphology on the Co₃O₄ nanowires 202. The carbon coating 206 confines the MnO₂ growth reaction to the surface of the nanowires 202, giving rise to well-constructed hybrid architectures. In other words, the 3D ordered amorphous carbon layers 206 function as a sacrificial reactive template to anchor the MnO₂ nanostructures 208 onto the Co₃O₄ nanowires 202. Without the sacrificial carbon template, no MnO₂ nanostructures are observable on the nanowires.

Ultrathin MnO₂ flake-like nanostructures or nanosheets 208 attached to the Co₃O₄ nanowires 202, for example branching from the surface or periphery of the Co₃O₄ nanowires 202, may be achieved. The MnO₂ flake-like nanostructures 208 may be formed branching uniformly from the surface of the Co₃O₄ nanowires 202, covering at least a portion of each Co₃O₄ nanowire 202 or substantially the entire surface of each Co₃O₄ nanowire 202.

The combination of MnO₂ flake-like nanostructures and Co₃O₄ nanowires with a unique morphology and independent electroactivities as a single engineered hierarchical architecture may substantially improve the electrochemical property of the overall electrode architecture. The synergistic effect from any two or all of the ultrathin MnO₂ flake-like nanostructures, the porous single-crystalline Co₃O₄ nanowires, and an ordered array configuration of the electrode architecture, may contribute to improved cycle performance and rate capability.

The array of Co₃O₄ nanowires, with well-defined single-crystalline nanostructure, serves as both the backbone and conductive connection for the MnO₂ flake-like nanostructures. The porous nature of the Co₃O₄ nanowires may enlarge the specific surface area. The ultrathin MnO₂ nanoflake-like structures may provide an enlarged contact area with electrolyte, may enable fast redox reaction, and may protect the inner structure of the Co₃O₄ nanowires, thereby improving the durability of the CoO nanoswires.

A method for forming an array of integrated core-shell nanostructures based on the array of MnO₂ flake-like nanostructures on Co₃O₄ nanowires will now be described by way of the following example. The plurality or array of MnO₂ flake-like nanostructures on Co₃O₄ nanowires was formed directly on a stainless steel current collector substrated based on the 3D interfacial carbon-assisted template growth method.

The plurality of Co₃O₄ nanowires were fabricated by a hydrothermal method with a reaction time of 5 hours. The Co₃O₄ nanowires grown may be porous and/or at least substantially single-crystalline. The Co₃O₄ nanowires grown may have a diameter of between about 50 nm and about 100 nm and a length of about 5 nm.

Subsequently, in order to fabricate the carbon modified Co₃O₄ nanowires, the nanowire array formed on the substrate was immersed into a 0.04 M aqueous glucose solution for about 24 hours, followed by carbonization at about 450° C. in Ar gas for about 2 hours. This may produce about 2-10 nm homogeneous carbon painting on the ordered Co₃O₄ nanowires.

After carbon deposition, the carbon modified nanowire array were placed into a Teflon (polytetrafluoroethylene)-lined stainless steel autoclave containing 0.03 M KMnO₄ solution, which was subsequently maintained at about 160° C. for about 1-5 hours. Results (not shown) illustrate that after 2 hours of hydrothermal reaction, the Co₃O₄ nanowire surface became rough, decorated by many tiny MnO₂ “buds”.

At the end of the process, the completed sample was taken out, washed with distilled water, and dried at about 60° C. to obtain the hybrid array of MnO₂ flake-like nanostructures on the Co₃O₄ nanowires. Ultrathin MnO₂ flake-like nanostructures or sheet-like nanostructures, having a thickness of less than 10 nm, branching uniformly on the nanowire surface were achieved after a 5-hour complete reaction between KMnO₄ and carbon. The nanosheets are interconnected with each other, forming a highly porous surface morphology. The as-obtained hybrid nanostructure array is macroscopically uniform and homogeneous and mechanically robust, with good mechanical adhesion to the substrate.

For comparison purposes, pure Co₃O₄ nanowire arrays, without the step of forming the MnO₂ flake-like nanostructures, were also prepared.

Characterisations were carried out by powder X-ray diffraction (XRD; Bruker D-8 Avance), scanning electron microscopy (SEM; JSM-6700F, 5.0 kV), transmission electron microscopy (TEM; JEM-2010FEF, 200 kV) equipped with an energy dispersive X-ray spectrometer (EDS), and Raman spectroscopy (Witech CRM200, 532 nm). The mass of electrode materials was measured on an AX/MX/UMX Balance (METTLER TOLEDO, Maximum=5.1 g; d=0.001 mg).

Electrochemical measurements were performed on an electrochemical workstation (CHI 760C, CH Instruments Inc., Shanghai) using a three-electrode mode in 1 M LiOH aqueous solution within the potential window of approximately −0.2 to 0.6 V. The MnO₂—Co₃O₄ hybrid array or the pristine Co₃O₄ nanowire array (≈1×3 cm²; Co₃O₄ mass: ≈2.1 mg, MnO₂ mass: ≈2.4 mg) was directly used as the working electrode. The reference electrode and counter electrode were Ag/AgCl and a platinum plate, respectively. Prior to the measurements, the array electrodes were sealed on all edges, except for the working surface area, with epoxy resin. Electrochemical impedance spectroscopy (EIS) measurements were performed by applying an AC voltage with 5 mV amplitude in a frequency range from 0.01 Hz to 100 kHz. Areal capacitance (Cₐ) and specific capacitance (Cₛₚ) were calculated using Equations 1 and 2, respectively, where I is the constant discharge current, t is the discharging time, ΔV is the voltage drop upon discharging (excluding the IR drop) or potential window, m is the total mass of the electrode material (e.g. the hybrid nanostructures), and S is the geometrical area of the electrode.

$$\begin{matrix}{C}_{a} = \frac{I \times t}{Δ V \times S} , & ( Equation 1 ) \\ {C}_{sp} = \frac{I \times t}{Δ V \times m} . & ( Equation 2 )\end{matrix}$$

FIG. 2B shows the Raman spectra of the Co₃O₄@MnO₂ hybrid nanostructure arrays obtained at different growth stages, illustrating the composition evolution. The spectrum of pure MnO₂ is also shown for comparison purposes.

FIG. 2C shows the X-ray diffraction (XRD) pattern of the 5-hour grown Co₃O₄@MnO₂ hybrid nanostructure array, which confirms the presence of crystalline birnessite-type layered MnO₂ and Co₃O₄. Based on the (001) peak of MnO₂, the thickness of the MnO₂ flake-like nanostructure is estimated to be approximately 4.3 nm. While not wishing to be bound by any theory, the sheet morphology is thought to have developed naturally as a result of the crystallographic habit of birnessite-type MnO₂.

TEM characterisations (image not shown) of an individual Co₃O₄@MnO₂ hybrid nanostructure show that thin flake-like nanostructures or nanosheets uniformly cover the surface of the porous Co₃O₄ nanowire, and may be observed to branch from a surface of the nanowire. In addition, high-resolution TEM (HRTEM) images (not shown) reveal an interplanar spacing of approximately 0.67 nm for two curling nanosheets, corresponding to the (001) plane of birnessite-type MnO₂.

FIG. 2D shows an energy-dispersive X-ray spectrometry (EDS) spectrum of the Co₃O₄@MnO₂ hybrid nanostructure array, which confirms the Co₃O₄ core/MnO₂ shell hierarchical structure. The EDS spectrum shows that a trace of K element was introduced into the interlayer of MnO₂ during the growth, while the Cu signal comes from the Cu grid used for carrying the hybrid nanostructure array during the EDS measurement. Both the Raman spectrum of FIG. 2B and the EDS spectrum of FIG. 2D show that no carbon remains in the hybrid nanostructure array.

The obtained electrode with the hybrid array of MnO₂ flake-like nanostructures on the Co₃O₄ nanowires may be used in a pseudocapacitor cell with a lithium hydroxide (LiOH) electrode. Electrochemical tests were carried out in a three-electrode configuration with a platinum (Pt) plate counter electrode and a silver/silver chloride (Ag/AgCl) reference electrode in 1 M LiOH aqueous electrolyte.

FIG. 2E shows a plot of cyclic voltammograms (CVs) of the Co₃O₄@MnO₂ hybrid nanostructure array after 5 hours of growth, at different scan rates of 10-50 mVs⁻¹. The CV for a pristine Co₃O₄ nanowire array at a scan rate of 50 mVs⁻¹ is also shown for comparison purposes. Two redox peaks at 0.33 V and 0.48 V (vs Ag/AgCl) are observed for the pristine Co₃O₄ array, which correspond to the reversible reactions of Co³⁺/Co⁴⁺ associated with anions OH⁻. As shown in FIG. 2E, in addition to the peaks from Co₃O₄, the CVs of the Co₃O₄@MnO₂ hybrid nanostructure array expand and become approximately rectangular. This CV shape change may be attributed to the presence of MnO₂, which adsorb cations (Li⁺) on the electrode surface from the electrolyte: [(MnO₂)_{surface}+Li⁺+ [symbol] (MnO₂⁻Li⁺)_{surface}] and suffer from possible intercalation or deintercalation of Li⁺. The significant increase in the CV integrated area leads to a much larger pseudocapacitance, as will be discussed later. The peak current values of the Co³⁺/Co⁴⁺ redox couple in the CV of the hybrid array are similar to those of the pristine Co₃O₄ array, indicating the full utilization of the underlying Co₃O₄ core despite the MnO₂ nanosheet cover.

The efficient cation (Li⁺) utilization from the electrolyte by MnO₂ may be further examined by recording the CV of the hybrid nanostructure array after a 2-hour reaction, as shown in FIG. 2F. It is observed that the integrated area contribution of MnO₂ to the CV becomes less for the 2-hour-grown array as compared to that after a 5-hour-growth, as less MnO₂ mass deposition happens within a shorter period. Co₃O₄ may not react with Li⁺ within the potential range of approximately −0.2 to 0.6 V vs Ag/AgCl (≈3.1 to 3.9 V vs Li⁺/Li).

The MnO₂—Co₃O₄ core/shell nanostructure array also demonstrates distinct galvanostatic charge-discharge behaviors, as shown in FIG. 2G. The result for the pristine Co₃O₄ nanowire array is also shown for comparison purposes. Compared to the pristine Co₃O₄ array, the Co₃O₄@MnO₂ hybrid array does not display fast potential drop from 0.3 V in the discharge curve, which is in line with the integrated area opening between approximately −0.2 and 0.3 V in the CV curve of FIG. 2E. The discharge areal capacitance of the hybrid array at 11.25 mA cm⁻² was measured to be 0.56 F cm⁻², which is about 4.15 times the capacitance of the pristine Co₃O₄ nanowire array (˜0.135 F cm⁻²). This result shows the advantage of an ordered hybrid pseudocapacitive material array for capacitance improvement.

FIG. 2H shows a plot of current density dependence of the areal capacitance and specific capacitance of both the hybrid nanostructure array and the Co₃O₄ nanowire array. With regard to the areal capacitance, within the current density from 4 to 44.7 mA cm⁻², the hybrid array delivers an areal capacitance many times greater than the Co₃O₄ array (in particular approximately 10 times at 44.7 mA cm⁻²). Moreover, at the highest current density (44.7 mA cm⁻², discharge at 7 seconds), the areal capacitance of the hybrid nanostructure array (0.4 F cm⁻²) is maintained at up to 56% of that measured at 4 mA cm⁻², which it is still much larger than the capacitance of pristine Co₃O₄ array determined at 4 mA cm⁻². This result is encouraging considering that the electrode is completely free of conductive additive and binder.

The specific capacitance (Cₛₚ) based on the mass of all active materials versus current density plots are also shown in FIG. 2H, which illustrates that the hybrid arrays exhibit superior Cₛₚ compared to the pristine Co₃O₄ array. At 2.67 A g⁻¹, a capacitance of 480 F g⁻¹ may be achieved. Even at a current density as high as 29.8 A g⁻¹, a Cₛₚ, of 267 F g⁻¹ may be achieved.

Cycling life tests over 5000 cycles for both the hybrid and pristine Co₃O₄ nanowire arrays were carried out at 11.25 mA cm⁻² and the results are shown in FIG. 2I. The hybrid core/shell nanowire array exhibits a good long-term electrochemical stability, as also observable from the very stable charge-discharge curves for the last 15 cycles (inset; with ≈99% Coulumbic efficiency). The capacitance loss after 5000 cycles is about 2.7% (97% retention). By contrast, 82.6% capacitance was retained (17.4% loss) for the pristine Co₃O₄ array.

The results show that the combination of MnO₂ and Co₃O₄ with a unique morphology and independent electroactivities into a single engineered hierarchical architecture may substantially enhance the electrochemical properties. While not wishing to be bound, it is believed that the synergistic contribution from the ultrathin MnO₂ nanosheets, the porous single-crystalline Co₃O₄ nanowires, and the ordered array configuration may account for the good cycle performance and rate capability, as schematically illustrated in FIG. 2J.

First, by growing directly from the Co₃O₄ nanowire scaffold 220, the surfaces of the MnO₂ nanosheets 222 may be well separated, making them substantially fully available to the Li⁺ in the electrolyte. The entirely exposed nanosheet edges may also facilitate the fast Li⁺ intercalation into the layered structure, thus enhancing the electrochemical kinetics. Electrochemical impedance spectroscopy result (not shown) further shows that the MnO₂ flake-like nanostructures 222 covering the Co₃O₄ nanowires 220 lead to a relatively smaller charge transfer resistance, which enhances the rate capability of the hybrid array.

Second, the ultrathin MnO₂ nanosheets 222 construct a highly porous structure on the Co₃O₄ nanowires 220. While substantially completely covered, the Co₃O₄ core nanowires 220 may still be accessed by OFF and initiate the redox reaction (please see FIG. 2E). In addition, the porous structure of the Co₃O₄ nanowires 220 may further increase the electrolyte-material contact area and enhance ion diffusion, which enables high-power energy storage. Furthermore, the directly grown array may ensure good mechanical adhesion and electrical connection to the current collector 224, avoiding the use of polymer binders and conducting additives which add extra contact resistance or weight.

The hybrid array electrode structure has robust mechanical stability. After long-term cycling, the hierarchical structure of the hybrid nanostructure array may be overall preserved with minimal structural deformation. While not wishing to be bound, the MnO₂ flake-like nanostructures are believed to serve as a protecting layer to maintain the Co₃O₄ structural integrity during the bulk redox reaction, which may otherwise weaken the nanowire due to the harsh and frequent phase variation.

To further demonstrate the synergistic effect of this hybrid array electrode configuration, the cycling performance of the hybrid nanostructure array at progressively increased current density was recorded and is shown in FIG. 2K. Even with sudden change of the current delivery, the electrode exhibits stable capacitance at each current density. After 900 times of continuous cycling at varying current densities, the current was changed back to 4 mA cm⁻². Under this condition, approximately 98.7% of the initial capacitance (0.7 F cm⁻²) may be recovered and maintained for another 600 cycles without noticeable decrease. This result highlights the capability of the 3D pseudocapacitive material-based hybrid array electrode to meet the requirements of both long cycle lifetime and good rate capability, for practical energy storage devices.

As illustrated by the results obtained, the electrode incorporating the hybrid nanostructure array show a high capacitance, in the order of a 4-10 fold increase in areal capacitance as compared to pristine Co₃O₄ nanowire array, depending on the current rates. For example, the hybrid array of MnO₂ flake-like nanostructures on the CO₃O₄ nanowires exhibit a specific capacitance of about 480 F/g at a current rate of about 2.67 A/g. The results also show good cycle performance (e.g. 97% capacitance retention after 5000 cycles), and remarkable rate capability (56% capacitance retention at a large current density of 44.7 mA/cm², charging/discharging within 7 seconds).

It should be appreciated that other types of combinations of active metal oxide materials may be employed to form an array of integrated core-shell nanostructures on a current collector substrate, for example MnO₂ flake-like nanostructures on NiO nanowires. Furthermore, other hybrid arrays may be formed based on chemical vapor deposition-grown SnO₂ nanowire array or solution-synthesized (e.g. hydrothermal) ZnO nanowire array as the scaffold on which MnO₂ flake-like nanostructures may be grown. Similar processing conditions as that employed for forming the MnO₂ flake-like nanostructures on Co₃O₄ nanowires may be used. In addition, it should be appreciated that the fabrication protocol may also be applicable to any carbon-modified surfaces or interfaces for the growth of rough MnO₂ thin films.

Various embodiments may also provide an electrode including a plurality of three-dimensional (3D) hybrid nanostructures of ultrathin nickel hydroxidenitrate (NiHON) flake-like nanostructures or nanoflakes on cobalt oxide (CoO) nanowires (termed CoO@NiHON), which provide robust hierarchical porosity and high specific surface area. The NiHON and CoO nanostructures may be employed as active electrode materials with relatively high capacitance. The hybrid nanostructures of flake-like nanostructures on nanowires may be grown on a substrate (e.g. a metal substrate, e.g. a nickel (Ni) foam substrate). The array of CoO nanowires may be formed directly on the substrate, in contact with a surface of the substrate, so as to enable fast electron transport. The CoO nanowires grown may be porous and/or at least substantially single-crystalline. The CoO nanowires grown may have a diameter of between about 50 nm and about 100 nm and a length of about 5 nm.

The array of CoO nanowires, with well-defined single-crystalline nanostructure, serves as both the backbone and conductive connection for the NiHON flake-like nanostructures. The porous nature of the CoO nanowires may enlarge the specific surface area. The ultrathin NiHON nanoflake-like structures may provide an enlarged contact area with electrolyte, may enable fast redox reaction, and may protect the inner structure of the CoO nanowires, thereby improving the durability of the CoO nanoswires.

The NiHON flake-like nanostructures may be formed as a result of Ni²⁺ hydrolysis on the surface of the CoO nanowires, which leads to the hydrotalcite-like nickel hydroxide structure intercalated with the NO₃⁻ groups.

The ultrathin NiHON flake-like nanostructures may be formed attached to the CoO nanowires, for example branching from the surface or periphery of the CoO nanowires. The NiHON flake-like nanostructures may be formed branching uniformly from the surface of the CoO nanowires, covering at least a portion of each CoO nanowire or substantially the entire surface of each CoO nanowire. The NiHON flake-like nanostructures may have a thickness of about 10 nm or less. The combination of NiHON flake-like nanostructures and CoO nanowires with a unique morphology and independent electroactivities as a single engineered hierarchical architecture may substantially improve the electrochemical property of the overall electrode architecture. The synergistic effect from any two or all of the ultrathin NiHON flake-like nanostructures, the porous single-crystalline CoO nanowires, and an ordered array configuration of the electrode architecture, may contribute to improved cycle performance and rate capability. The hierarchical structure of the plurality of hybrid NiHON flake-like nanostructures and CoO nanowires is overall preserved with minimal structural deformation.

A method for forming an array of NiHON flake-like nanostructures on porous CoO nanowires will now be described by way of the following example, via a facile two-step hydrothermal route, which may be scaled up. The plurality or array of NiHON flake-like nanostructures on CoO nanowires was formed directly on a three-dimensional (3D) nickel (Ni) foam current collector. Nickel foam is suitable as a cost-effective substrate because of its high conductivity and 3D network structure, which may reduce the diffusion resistance of electrolyte, provide ideal electron pathway even in a very rapid charge/discharge reaction, and load more active materials per unit electrode area due to its high surface area.

The plurality of CoO nanowires were fabricated on the nickel foam substrate by a hydrothermal method. Approximately 0.582 g Co(NO₃)₂ and 0.6 g urea were dissolved in 50 mL deionized water to obtain a homogeneous solution. The obtained homogeneous reaction solution was then transferred into Teflon-lined stainless steel autoclave with a piece of clean nickel foam (10×15×0.1 mm³, 100 PPI (pores per linear inch), 330 g/m², Changsha Lyrun Material Co., Ltd. China) immersed into the reaction solution.

After about 8 hours of growth at about 95° C., the as-prepared precursors were removed from the autoclave and annealed under a constant flow of argon (50 sccm) at about 450° C. for about 2 hours. Then, the nickel foam with the plurality of CoO nanowires was immersed into a 0.1 M Ni(NO₃)₂ aqueous solution and maintained at about 85° C. for about 5 hours during the hydrothermal growth process.

At the end of the process, the completed sample was removed from the Ni(NO₃)₂ aqueous solution and cooled to room temperature. An array of NiHON flake-like nanostructures on CoO nanowires may be obtained, in which the NiHON flake-like nanostructures are grown branching from the periphery of the CoO nanowires.

For comparison purposes, pure CoO nanowire arrays, without the step of forming the NiHON flake-like nanostructures, were also prepared.

Characterisations were carried out by scanning electron microscopy (SEM; JSM-6700F, 10.0 kV), transmission electron microscopy (TEM; JEM-2010FEF, 200 kV) equipped with an energy dispersive X-ray spectrometer (EDS), powder X-ray diffraction (XRD; Bruker D-8 Avance) measurements, and Fourier transform infrared (FTIR) spectrum was recorded on a Bruker Vertex 80V HYPERION 2000 Microscope using MCT detector. The mass of electrode materials was measured on an AX/MX/UMX Balance (METTLER TOLEDO, Maximum=5.1 g; d=0.001 mg).

Electrochemical measurements (ZAHNER ZENNIUM Electrochemical Workstation) were performed in a three-electrode electrochemical cell at room temperature using a 1 M NaOH aqueous solution. The nickel foam supported hybrid nanostructures (≈1 cm² area; CoO mass: ≈2.2 mg; NiHON mass: 0.8 mg) was employed directly as the working electrode. A platinum (Pt) plate and silver/silver chloride (Ag/AgCl) were used as the counter electrode and the reference electrode, respectively. All potentials were referenced to the reference electrode. The weight in specific capacitance (F g⁻¹) and current rate (A g⁻¹) were calculated based on the whole mass of the two active materials (CoO and NiHON). Electrochemical impedance spectroscopy (EIS) measurements were carried out by applying an AC voltage with 1 mV amplitude in a frequency range from 0.1 Hz to 100 kHz at open circuit potential.

SEM characterisations (image not shown) of the aligned CoO nanowires formed show that the nanowires have a diameter of about 60-100 nm and a length of about 2-3 μm and are highly porous. SEM characterisations (image not shown) of the CoO@NiHON hybrid nanostructures on the nickel foam show that the nickel foam was uniformly covered with the hybrid nanostructures, and that the CoO “nanostems” are tightly bonded and substantially covered with “leaves” of the NiHON nanoflakes or flake-like nanostructures, such that the space between the CoO nanowires is abundantly utilized, which may increase the energy and power per unit area. The nanoflakes are formed because of Ni²⁺ hydrolysis on the CoO nanowire surface, which leads to the hydrotalcite-like nickel hydroxide structure intercalated with the NO³⁻ groups.

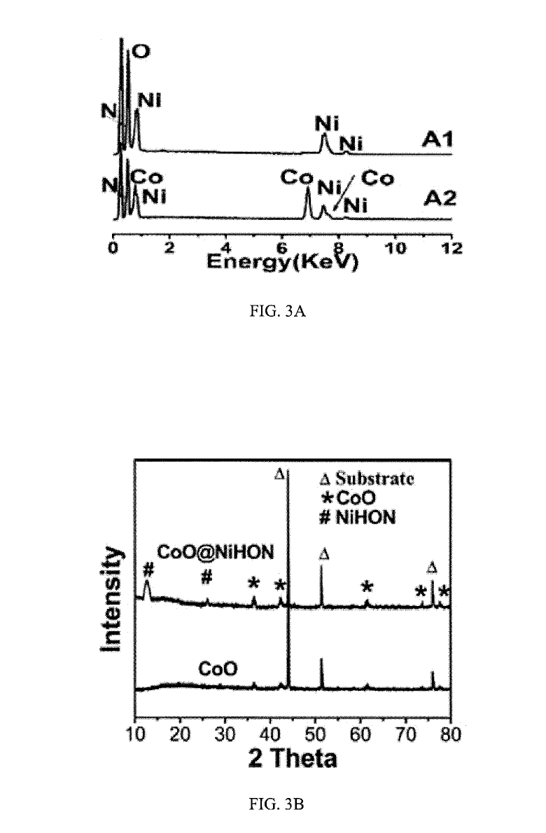

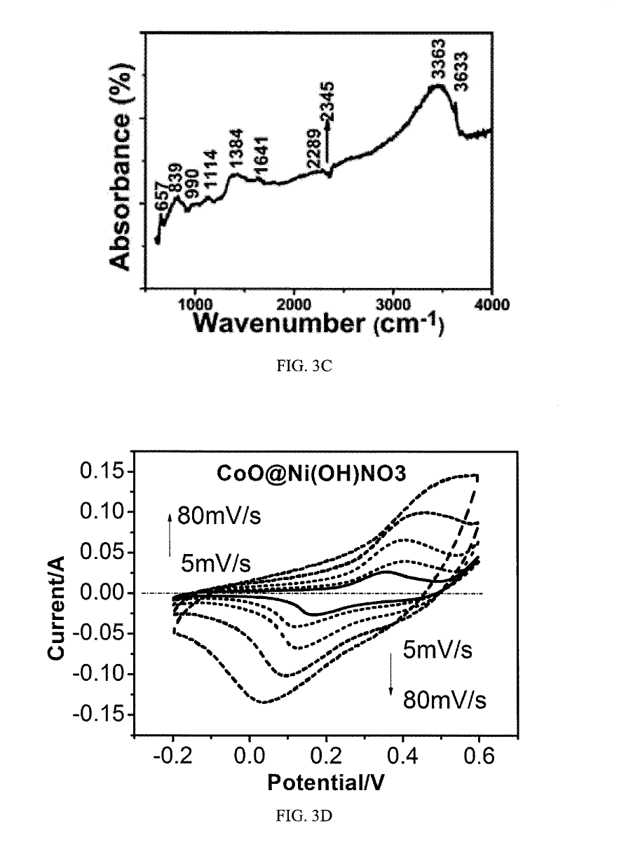

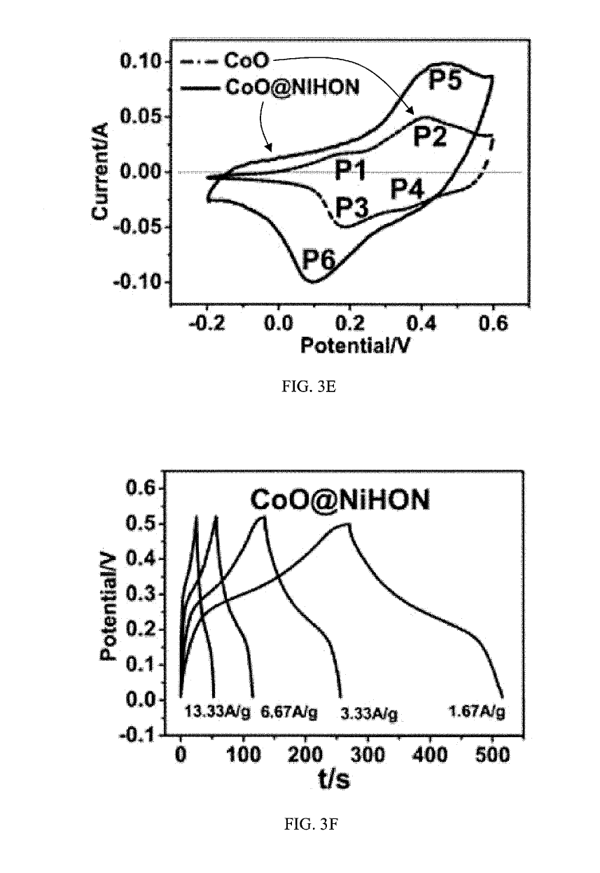

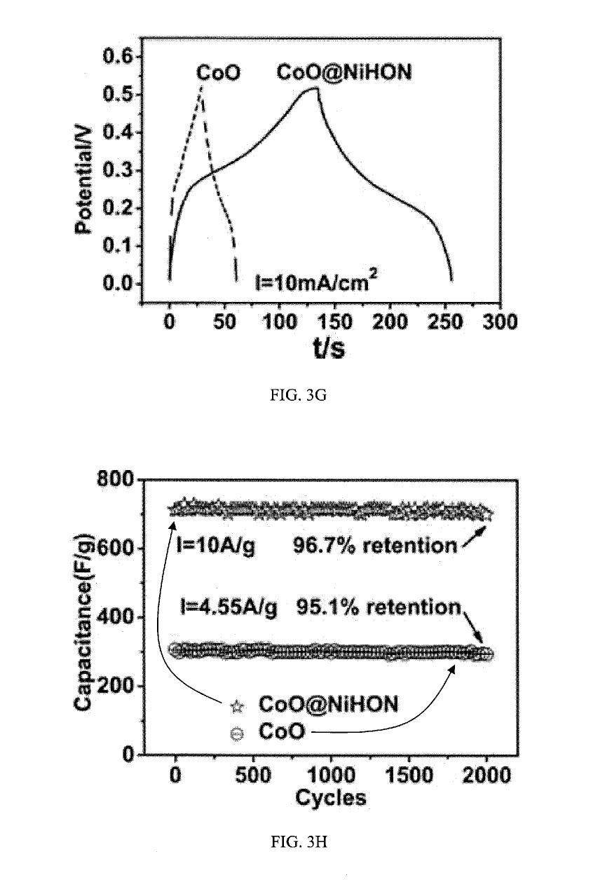

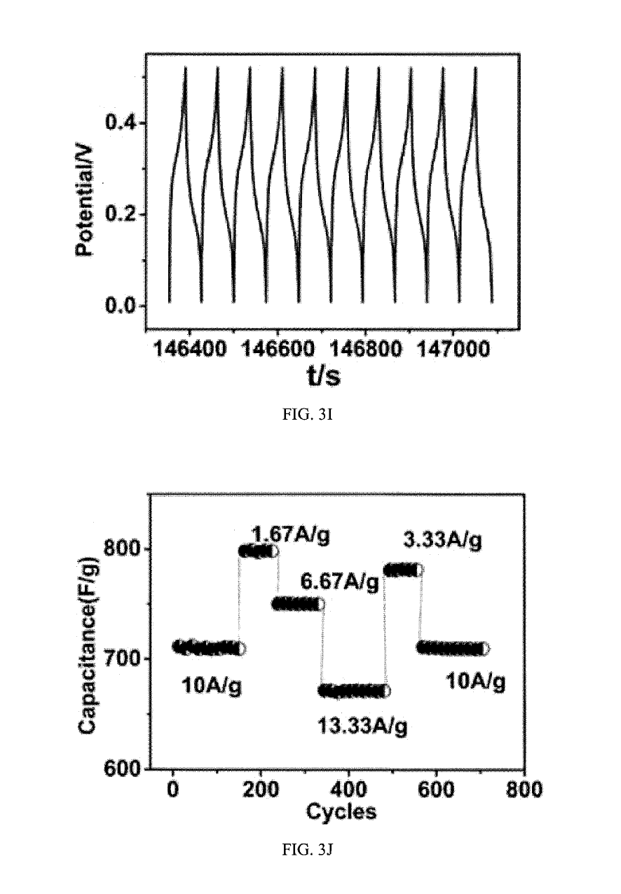

TEM characterisations (images not shown) of an individual CoO@NiHON hybrid nanostructure show a hierarchical hybrid nanostructure where the surface of the CoO nanowire is substantially fully covered with ultrathin NiHON nanoflakes, which stretch out about 100 nm. EDS analysis at two areas (A1: flakes; A2: flakes and nanowire) reveals the elements of O, N and Ni in the “leaves”, as shown in FIG. 3A.

FIG. 3B shows the X-ray diffraction (XRD) pattern of the arrays of CoO@NiHON hybrid nanostructures and CoO nanowires on the nickel foam. The XRD pattern for the CoO nanowires corresponds with the reported pattern of CoO (JCPDS, card no: 48-1719). As shown in FIG. 3B, after the second step growth, two other peaks appear in the XRD pattern of the hybrid nanostructures, which correlate with Ni₃(NO₃)₂(OH)₄ (JCPDS, card no: 22-0752).

FIG. 3C shows the Fourier transform infrared (FTIR) spectrum of the array of CoO@NiHON hybrid nanostructures, where the results provide further support for the formation of Ni-based hydroxidenitrate. A group of peaks in the range of 990 cm⁻¹ to 1384 cm⁻¹ represent the nitrate anion. Two peaks observed at 657 cm⁻¹ and 3633 cm⁻¹ are associated with the φ-OH vibrations and ν-OH stretching, respectively. Three peaks at 839 cm⁻¹, 1641 cm⁻¹, and 3363 cm⁻¹ are associated with the vibrations of H₂O.

FIG. 3D shows a plot of cyclic voltammograms (CVs) of the CoO@NiHON hybrid nanostructure array on nickel foam, at different scan rates of 5, 10, 20, 40 and 80 mV s⁻¹, while FIG. 3E shows a plot of cyclic voltammogram (CV) of the CoO@NiHON hybrid nanostructure array on nickel foam at a scan rate of 40 mVs⁻¹. For comparison purposes, the cyclic voltammogram (CV) of CoO nanowires on nickel foam at the scan rate of 40 mVs⁻¹ is also shown in FIG. 3E, from which two pairs of redox peaks may be observed: P1 and P3 due to the reaction (CoO+OH⁻ [symbol] CoOOH+e⁻), and P2 and P4 due to the reaction (CoOOH+OH⁻ [symbol] CoO₂+H₂O+e⁻). The redox peaks due to the Ni foam may be negligible.

Comparison of the results shown in FIG. 3E illustrates the contribution of the ultrathin NiHON nanoflakes. The CV curve of the CoO@NiHON hybrid nanostructures not only fully encompassed all the four peaks of the CoO nanowires, but greatly expanded, thus increasing the integrated area, which means that the hybrid nanostructures have a much larger capacitance compared to only the CoO nanowires. The expanded peaks (P5 and P6) may be attributed to the reaction between Ni²⁺/Ni³⁺ and anions OH⁻. This means that the ultrathin NiHON nanoflakes did not restrain the inside CoO nanowires from the reaction with OH⁻, but introduces another electrochemical redox reaction to boost the charge storage capability. Such an observation may be supported by means of charge-discharge measurements.

FIG. 3F shows a plot of charge/discharge curves for the CoO@NiHON hybrid nanostructure array on nickel foam at different current densities between 0.01 V-0.52 V. The specific capacitance, Cₛₚ, may be calculated based on Equation 2 above.

A nickel foam under the same pretreatment was also tested independently, which shows a capacitance of ˜2 F g⁻¹ at a current density of 5 mA cm⁻², contributing 2.89% of the total capacitance of the hybrid nanostructures. In order to illustrate the contribution from the active materials, in all of the following results the small contribution of the Ni foam was subtracted. From Equation 2, the hybrid nanostructures exhibit Cₛₚ of 671.3 F g⁻¹, 749.9 F g⁻¹, 781.8 F g⁻¹ and 798.3 F g⁻¹ at different discharge currents of 13.33 A g⁻¹, 6.67 A g⁻¹, 3.33 A g⁻¹ and 1.67 A g⁻¹, respectively.

FIG. 3G shows a plot of charge/discharge curves for the CoO@NiHON hybrid nanostructure array and the CoO nanowires on nickel foams at the areal charge-discharge current of 10 mA cm⁻². From the comparison, as a results of the participation of NiHON, the hybrid nanostructures exhibit much better electrochemical performance when compared with the CoO nanowires alone (which has a Cᵥ of 307 F g⁻¹ at a current density of 4.55 A g⁻¹). Furthermore, where the CoO and NiHON are simply added together with the same mass ratio to that in the hybrid nanostructures, the Cₛₚ, of this addition is only 545 F g⁻¹, thereby illustrating the merits of the uniform hybrid nanostructures which have substantially single-crystalline CoO backbones and ultrathin NiHON nanoflake shells.

The electrochemical stability of the CoO nanowires and the hybrid nanostructures are illustrated in FIG. 3H, which shows a plot of cycling performance of both the CoO@NiHON hybrid nanostructures and pristine CoO nanowires arrays (2000 cycles). After 2000 cycles of charge and discharge, both arrays do not show observable loss of capacitance (less than 5%), and the hybrid nanostructures with a 96.7% capacitance retention showed better durability than the CoO nanowires alone (which has a 95.1% capacitance retention).

FIG. 3I shows a plot of the charge-discharge curves of the last 10 cycles for the array of CoO@NiHON hybrid nanostructures. Even after long-time cycling, the hybrid nanostructures may still maintain a good electrochemical reversibility with 98.9% Coulombic efficiency. Without wishing to be bound, the good electrochemical stability of the array of hybrid nanostructures may be attributed to the following: First, the ordered CoO nanowires are grown tightly on the nickel foam substrate and provide an excellent conducting connection with the NiHON nanoflakes; Second, the NiHON nanoflakes, filled on the surface or periphery of the CoO nanowires, may prevent the CoO “stems” from collapsing during the harsh long-duration reactions in the electrolyte.

FIG. 3J shows a plot of cycling stability of the CoO@NiHON hybrid nanostructures array at progressively varied current density, illustrating the current density dependence of the cycling performance. During the first 150 cycles with a charge-discharge current density of 10 A g⁻¹, the array of hybrid nanostructures shows a substantially stable Cₛₚ of approximately 710 F g⁻¹. In the following 400 cycles, although the charge-discharge rate changes successively, the hybrid nanostructures maintain stable capacitances in each situation. When the current was changed back to 10 A g⁻¹, a substantially fully recovered Cₛₚ of approximately 710 F g⁻¹ may be observed in the subsequent 150 cycles, which shows that the hybrid nanostructures have excellent rate capability.

Electrochemical impedance spectroscopies (EIS) of the CoO nanowires and the hybrid NiHON—CoO nanostructures (results not shown) show that the hybrid NiHON—CoO nanostructures has a lower diffusion resistance, which may be attributed to the ultrathin NiHON nanoflakes with large surface area that enhance the electrode materials utilization and thus facilitates the supply of Off to the entrance of the CoO nanopores and the nickel foam micropores. In addition, the hybrid NiHON—CoO nanostructures exhibit lower bulk resistance and charge-transfer resistance than CoO nanowires. The combination of low diffusion and electron-transfer resistances may contribute to the excellent electrochemical performance of the hybrid nanostructure.

As illustrated by the results obtained, the electrode incorporating the hybrid NiHON—CoO nanostructures show an excellent electrochemical stability over more than 2000 charge-discharge cycles, with a capacitance loss of less than 5% after the 2000 charge-discharge cycles, high rate performance (e.g. 671.3 F/g at a high current rate of 13.33 A/g), and a high specific capacitance of 798.3 F at a current rate of about 1.67 A g⁻¹. The cost-effective fabrication and excellent electrochemical performance provide great potential for such hybrid 3D nanostructures as an active electrode for electrochemical supercapacitors.

Flake-Like Nanostructures on a Substrate

Nanoporous metal oxides and metal hydroxides may be suitable for energy storage applications, because of a substantially increased surface area due to the porous nature of the nanostructures. Various embodiments may provide an electrode including nanoporous NiO nanoflakes or nanowalls formed on a substrate (e.g. macroporous foam). The porous flake-like nanostructures may contribute to a much higher specific capacitance as compared to solid flakes.

In various embodiments, the nanoporous NiO nanoflakes or nanowalls may be formed, by means of a hydrothermal reaction or process, on any type of metallic substrate acting as a current collector. The nanoporous NiO nanoflakes may be formed directly on the substrate, in contact with a surface of the substrate, so as to enable fast electron transport. The NiO flake-like nanostructures may be formed uniformly on the substrate. The NiO flake-like nanostructures may have a thickness of about 10 nm or less.

The nanoporous NiO nanoflakes may be spaced apart or separated, with free spaces in between, for example individual nanoflakes may be separated or a portion of a NiO nanoflake may be separated from an adjacent NiO nanoflake while the remaining portions of the adjacent NiO nanoflakes may be cross-linked. The separation distance may be about 50 nm or more.

In various embodiments, the substrate and/or the NiO flake-like nanostructures may be coated, for example by means of electrochemical deposition, with another metal oxide or metal hydroxide, for example nickel hydroxide (Ni(OH)₂) which has a flake-like structure, so as to utilise the free spaces in between the NiO flake-like nanostructures. This may provide an enlarged surface area and therefore a much higher specific capacitance may be possible.

In further embodiments, CoO flake-like nanostructures or nanowalls may be formed instead of the NiO flake-like nanostructures. The secondary Ni(OH)₂ flake-like nanostructures may also be formed.

A method for forming CoO flake-like nanostructures on a commercial three-dimensional (3D) nickel (Ni) foam current collector using a hydrothermal process will now be described by way of the following example, which may be scaled up. The nickel foam was used as the supporting electrode that may serve as a current collector for a pseudocapacitor cell incorporating the CoO flake-like nanostructures, as well as for the purpose of electrodeposition of secondary metal oxide nanostructures, if desired.

The nickel foam (20×50×0.1 mm³, 100 PPI, 330 g/m², Changsha Lyrun Material Co., Ltd. China) was pretreated with concentrated hydrochloric acid (HCl) solution, absolute ethanol and deionized water, each for 5 minutes, to thoroughly clean the surface of the nickel (Ni) foam. The Ni foam, with a portion thereof left as a supporting electrode for subsequent electrodeposition/testing, was then placed in a Teflon-lined stainless steel autoclave with a 50 mL homogeneous solution containing 5 mmol Co(NO₃)₂.6H₂O and 10 mmol HMT (hexamethylene tetramine). After 8 hours of growth at about 95° C., the as-prepared precursors were removed from the autoclave and annealed under a constant flow of argon (50 sccm) at about 450° C. for about 2 hours.

In order to increase the areal capacitance, hybridization with an additional metal oxide was carried out. The aligned and cross-linked CoO nanowalls served as a robust and conductive scaffold for the loading of additional pseudoactive nanomaterial. In order to achieve synergy, the newly introduced material should contribute effective specific capacitance, enlarge the surface area but not prevent contact between the CoO nanowalls and ions in the electrolyte, and maintain the structural integrity. Electrodeposition was used as a controllable method to coat the surface of the CoO nanowalls with another pseudocapacitive metal oxide, such as MnO₂ and Ni(OH)₂, by changing the solution for electrodeposition. Both MnO₂ and Ni(OH)₂ show a flake-like structure and thus are suitable as a supercapacitor electrode material. Such porous and flake hybrid nanoscale metal oxides may also be useful in lithium ion batteries and gas sensing.

A method for forming secondary Ni(OH)₂ flake-like nanostructures on the as-obtained CoO flake-like nanostructures on Ni foam current collector by means of electrodeposition will now be described by way of the following example.

For the deposition of Ni(OH)₂ nanostructures, the nickel foam with CoO flake-like nanostructures or nanowalls (mass loading: 4.3 mg cm⁻²) as obtained using the method above was used as a working electrode for electrodeposition of Ni(OH)₂. Electrodeposition was carried out in a Chenhua CHI760D model Electrochemical Workstation (Shanghai), with a three-electrode setup having Ag/AgCl and a platinum plate as the reference and counter electrodes respectively, and an aqueous solution of 0.1 M Ni(NO₃)₂ as the electrolyte.

The electrodeposition process was conducted at a constant current of approximately 1 mA for different durations between 2 minutes and 30 minutes to ensure the conformal coating of Ni(OH)₂ nanostructures on the CoO flake-like nanostructures. The mass of the deposited Ni(OH)₂ was calculated using Faraday's law. After deposition, the as prepared electrode incorporating the Ni(OH)₂ flake-like nanostructures and the CoO flake-like nanostructures on nickel foam was washed with water several times and then placed in a vacuum oven at about 60° C. for about 2 hours for drying and annealing. The mass of deposited Ni(OH)₂ nanomaterial was again obtained by the weight difference before and after electrodeposition.

Characterisations were carried out by powder XRD (Bruker D-8 Avance), SEM (JSM-6700F, 10.0 kV), TEM (JEM-2010FEF, 200 kV), and FTIR spectroscopy (Bruker Vertex 80V HYPERION 2000 Microscope with mercury cadmium telluride (MCT) detector). The mass of electrode materials was measured on an AX/MX/UMX Balance (METTLER TOLEDO, maximum=5.1 g; d=0.001 mg). Nitrogen adsorption/desorption isotherms were measured on a Micromeritics TriStar 3000 porosimeter (mesoporous characterization) and a Micromeritics ASAP 2020 (microporous characterization) at 77 K. All samples were outgassed at 100° C. for 6 hours under vacuum before measurements were recorded. The specific surface areas were calculated using the BET method.

Electrochemical measurements (CHI 760D Electrochemical Workstation) were performed in a three-electrode electrochemical cell at room temperature using 1 M NaOH as the electrolyte. The nickel-foam-supported hybrid nanostructure (˜1 cm² area) acted directly as the working electrode. A Pt plate and Ag/AgCl were used as the counter electrode and the reference electrode, respectively. All potentials were referenced to the reference electrode. The weight-specific capacitance (F g⁻¹) and current rate (A g⁻¹) were calculated based on the whole mass of the two active materials, CoO and Ni(OH)₂.

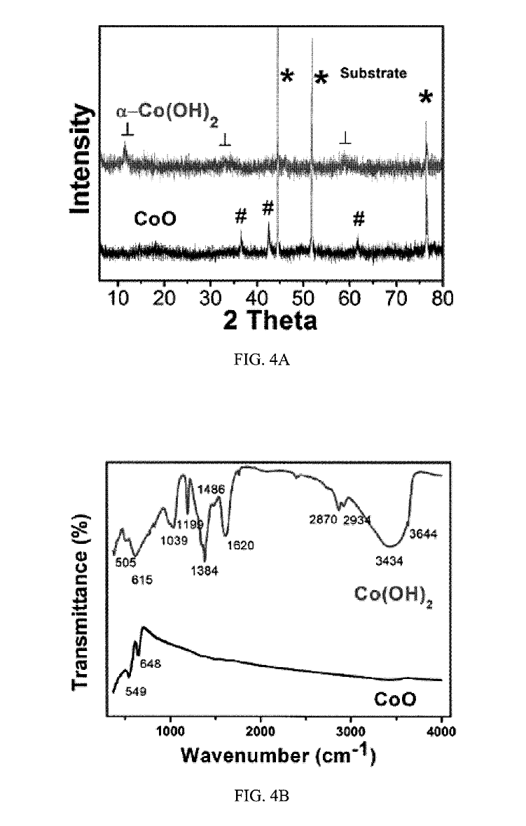

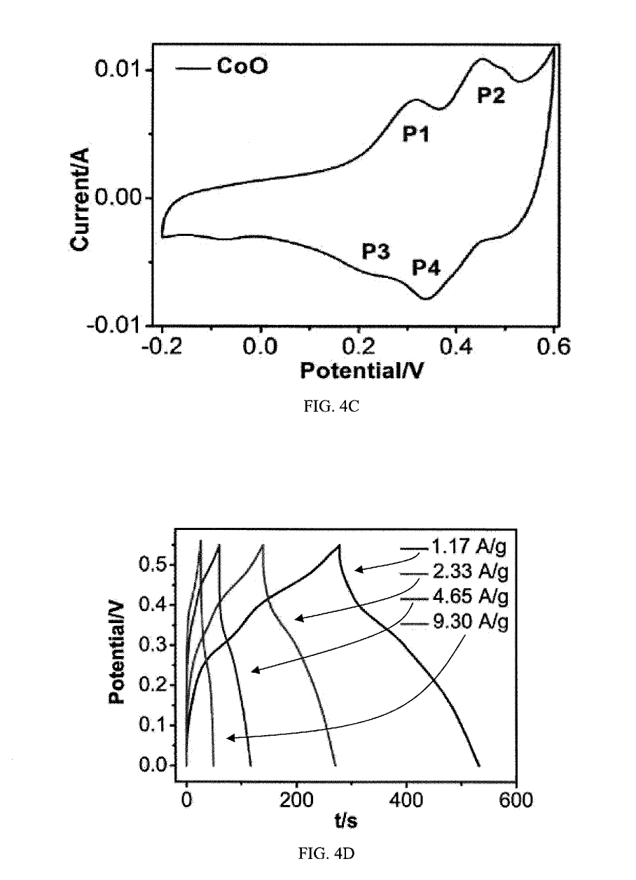

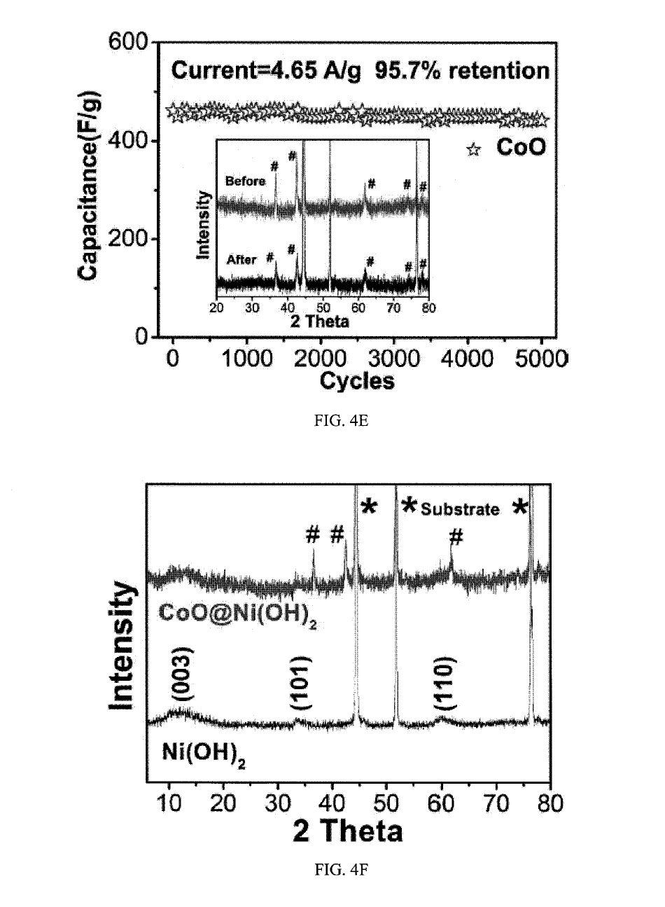

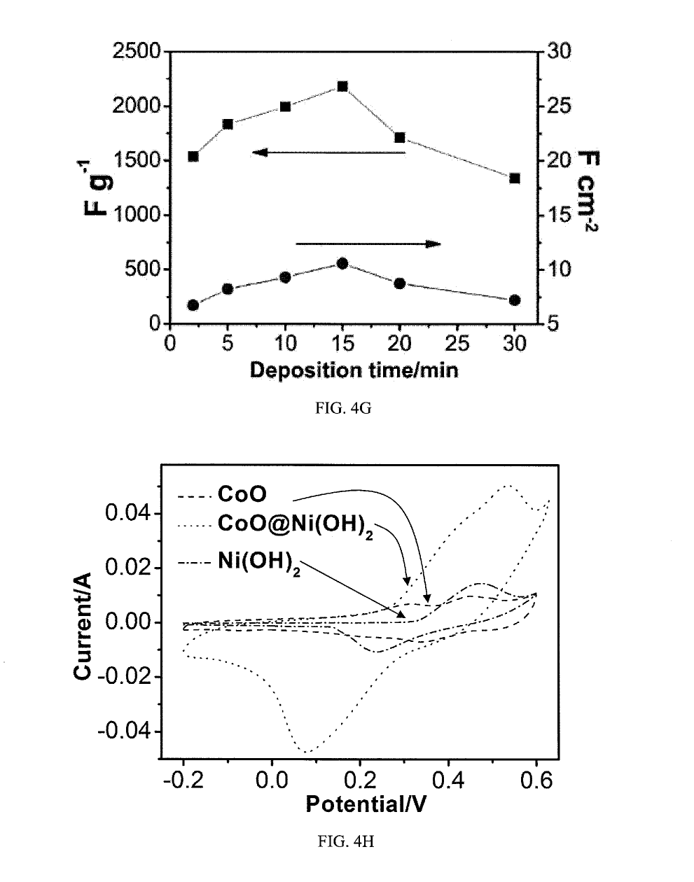

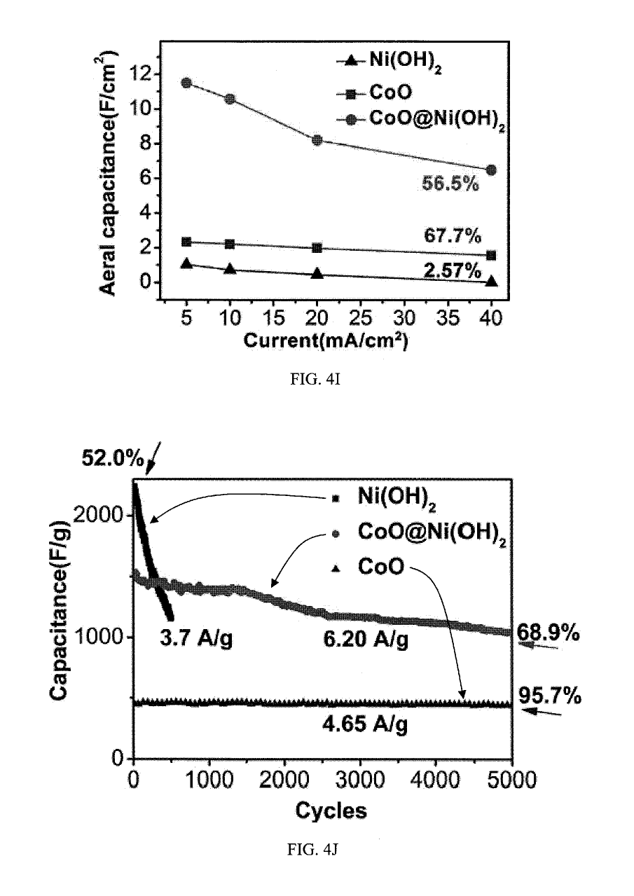

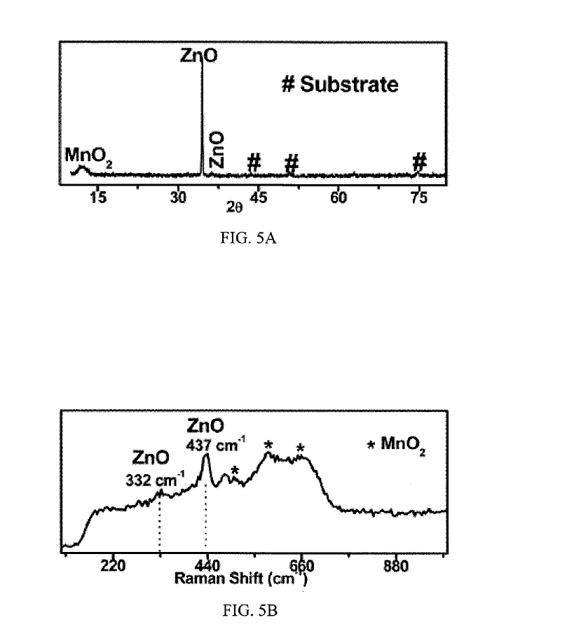

FIG. 4A shows the X-ray diffraction (XRD) patterns showing the transformation of Co(OH)₂ to CoO after thermal annealing. The XRD pattern of the as-prepared sample matches the reported pattern of Co(OH)₂ (JCPDS card no: 74-1057). The thermal annealing converted the Co(OH)₂ into the CoO phase, as may be observed from the bottom XRD pattern in FIG. 4A (JCPDS card no: 48-1719).

This transformation may be further supported by the Fourier transform infrared (FTIR) spectra as shown in FIG. 4B. Before annealing, two peaks observed in the range 500-700 cm⁻¹ represent v-Co—O; peaks at 1199 cm⁻¹ and 1384 cm⁻¹ are associated with NO₃⁻; two peaks at 1039 cm⁻¹ and 1486 cm⁻¹ are correlated with CO₃²⁻; peaks at 2870 cm⁻¹ and 2934 cm⁻¹ are assigned to C—H vibrations; and the other two peaks at 1620 cm⁻¹ and 3644 cm⁻¹ are associated with the vibrations of H₂O. After annealing, most of these peaks disappeared while the Co—O peaks remained strong.

SEM characterisations (images not shown) of the aligned CoO nanowalls grown directly on the nickel foam show that the macroporous nickel foam is covered with the CoO nanostructures, and that nanowalls with a size of 4-5 μm are aligned vertically on the nickel foam and have a cross-linked character. The overall alignment may be beneficial to the charge transport and ion diffusion without the necessity of binder blocks. SEM characterisations (images not shown) of an individual CoO nanowall show a highly porous structure with pore diameters around or below 100 nm.

TEM characterisations (images not shown) of an individual CoO nanowall show a porous structure and that the nanowall is composed of small nanobricks tightly interconnected with each other. Further SEM and TEM characterisations (images not shown) illustrate that the annealing step converted Co(OH)₂ to highly porous CoO, during which the architecture of the nanowalls was well preserved.

The electrochemical properties were determined to evaluate the supercapacitor applications of these porous nanostructures. FIG. 4C shows a plot of cyclic voltammogram (CV) of the CoO nanowalls on nickel foam at a scan rate of 2 mVs⁻¹.

Two pairs of redox peaks may be observed, which correspond to the reversible conversion between different cobalt oxidation states. The reactions between P1 and P3 are (CoO+OH⁻ [symbol] CoOOH+e⁻), and the reactions between P2 and P4 are (CoOOH+OH⁻ [symbol] CoO₂+H₂O+e⁻).

FIG. 4D shows a plot of charge/discharge curves for the CoO nanowalls at different current densities between 0 and 0.55 V. The areal capacitance (Cₐ) and specific capacitance (Cₛₚ) may be determined from Equations 1 and 2 above respectively. The specific capacitances, Cₛₚ, of the CoO nanowalls were determined to be 364.2 F g⁻¹, 461.7 F g⁻¹, 515.6 F g⁻¹, and 539.8 F g⁻¹ at discharge currents of 9.30 A g⁻¹, 4.65 A g⁻¹, 2.33 A g⁻¹, and 1.17 A g⁻¹, respectively. The high Cₛₚ may be attributed to the porous structure of the walls, which provides more surface area in contact with the electrolyte, and therefore more active material may effectively contribute to the capacitance. The areal capacitance, Cₐ, of the CoO nanowalls was determined to be 2.32 F cm⁻².

The nickel foam substrate may affect the final CV curve with a small capacitance contribution. In order to illustrate the contribution of the active CoO material, in all of the following results, the small contribution of the Ni foam was subtracted.

The charge-discharge cyclic stability of the CoO nanowalls was further determined. FIG. 4E shows a plot of cycling performance of the CoO nanowalls (5000 cycles). The inset shows the XRD patterns before cycling and after 5000 cycles, showing the structural preservation. As shown in FIG. 4E, after 5000 charge-discharge cycles at a current density of 4.65 A g⁻¹, the structure shows only a small loss of capacitance (less than 5%). The good long-term electrochemical stability may also be demonstrated by comparing the XRD patterns of the CoO nanowalls before and after 5000 cycles (as shown in the inset in FIG. 4E), where after the long-time cycling, minimal change of the CoO peaks was observed and no other impurity was observable. The morphology of the CoO nanowalls was determined after 5000 cycles via scanning electron microscopy (image not shown), which showed that the porous structure was fully maintained and no obvious changes were observed. Owing to its highly porous and crystalline structure and the direct connection with the macroporous nickel foam, the CoO nanowalls exhibited not only high capacitance but also long cycling stability, and therefore suitable for commercial applications in high-demand energy storage.

XRD was performed on the sample after Ni(OH)₂ electrodeposition on the CoO nanowalls (termed CoO@Ni(OH)₂), as shown in FIG. 4F. New peaks appearing in the XRD pattern of the hybrid CoO@Ni(OH)₂ structure may be indexed to α—Ni(OH)₂.

SEM characterisations (images not shown) of the CoO@Ni(OH)₂ hybrid nanostructure obtained after 15 minutes electrodeposition show that the leaf-like Ni(OH)₂ thin layers cover uniformly the surface of the CoO nanowalls. The pores of the CoO nanowalls may also be filled with the thin layers.

SEM and TEM characterisations (images not shown) of the sample after different electrodeposition times were carried out. The results show that the size and coverage of the Ni(OH)₂ nanolayers depends on the deposition time, where the nanolayers grow individually and then percolate until full coverage of the CoO nanowall surface was achieved. Correspondingly, the variation of the capacitance with the electrodeposition time was determined and shown in FIG. 4G. All the samples show very high specific capacitance (>1200 F g⁻¹) and high areal capacitance (>6 F cm⁻²). The highest capacitance corresponds to 15 minutes of deposition of Ni(OH)₂. These results illustrate the convenience of electrodeposition in tailoring the nanoelectrode surface, and may help to optimize the electrodeposition condition so that the resulting Ni(OH)₂ nanomembranes may not have detrimental effect by blocking the spaces between the CoO nanowalls, which may prohibit fast ion transfer.

The CoO@Ni(OH)₂ hybrid nanostructure demonstrates enhanced electrochemical properties as a supercapacitor electrode. For a direct comparison, the CV curves under the same scan rate and the areal capacitances of pure CoO, Ni(OH)₂ and hybrid CoO@Ni(OH)₂ were determined and shown in FIG. 4H. As shown in FIG. 4H, as compared to the CV curves of the CoO nanowalls and the Ni(OH)₂ nanolayers directly deposited on the nickel foam, the enclosed area corresponding to the CV behavior of the hybrid electrode, with 15 minutes electrodeposition at a scan rate of 2 mV s⁻¹, is greatly increased, indicative of a larger capacitance.

FIG. 4I shows a plot of areal capacitance of the three structures Ni(OH)₂, CoO, and CoO@Ni(OH)₂ as a function of current densities. The percentages show the capacitance retention when the current was increased from 5 to 40 mA cm⁻². As shown in FIG. 4I, the capacitance of the hybrid electrode may be observed to be approximately 3 times the simple addition of the two components. For example, the areal capacitance reaches 11.49 F cm⁻² at a current density of 5 mA cm⁻², whereas the values for the individual CoO and Ni(OH)₂ are 2.3 F cm⁻² and 1 F cm⁻².

The capacitance improvement of the hybrid electrode may also be observed from the charge-discharge behaviours (results not shown). At the same current density of 10 mA cm⁻², the capacitance of the hybrid nanostructure is increased approximately 4.8 times as compared to pure CoO nanowalls (with only a small amount of Ni(OH)₂ deposited, corresponding to a 12.6% mass increase). The hybrid nanostructure has specific capacitances of 1340.9 F g⁻¹, 1694.2 F g⁻¹, 2185.9 F g⁻¹, and 2374.0 F g⁻¹ at discharge currents of 8.26 A g⁻¹, 4.13 A g⁻¹, 2.07 A g⁻¹, and 1.03 A g⁻¹, respectively.

The large improvement in the areal capacitance may be attributed to a synergy between the two oxides of CoO and Ni(OH)₂ flake-like nanostructures. The core CoO nanowalls with excellent electrochemical stability and high surface area act as a robust and conductive host for Ni(OH)₂, while the addition of Ni(OH)₂ nanolayers not only contributes another effective redox reaction to the capacitance (reaction between Ni²⁺/Ni³⁺ and OH⁻ anions), but also enlarges the surface area of the whole electrode. The surface areas of the hybrid electrode (15 minutes of electrodeposition) measured by the Brunauer-Emmett-Teller (BET) method is about 9.12 m² g⁻¹, as compared to 7.66 m² g⁻¹ for the CoO nanowall-covered nickel foam and 0.01 m² g⁻¹ for the bare nickel foam.

The capacitances generally drop sharply with increasing discharge rate. As shown in FIG. 4I, the electrode of Ni(OH)₂ nanolayers directly deposited on nickel foam had only 2.57% retention when the discharge current was increased by a factor of eight from 5 to 40 mA cm⁻². In contrast, for the hybrid nanostructure, 56.5% of the capacitance (6.49 F cm⁻²) may be maintained, which may be attributed to a positive role of the porous CoO nanowalls in the overall supercapacitor performance.

The synergy between the CoO and Ni(OH)₂ may also be seen from the cycling performance. Results (not shown) show that the Ni(OH)₂ nanolayers directly deposited on nickel foam are not electrochemically stable and have poor cycling behavior. When they are hybridized with the CoO nanowalls, it is observed that the capacitance of the coupled electrode decays much more slowly than that of the pure Ni(OH)₂, as shown in FIG. 4J. When compared at a current density of 30 mA cm⁻², the hybrid CoO@Ni(OH)₂ electrode has 68.9% capacitance retention after 5000 cycles, whereas the Ni(OH)₂— nanolayer electrode has only 52.0% after 500 cycles. This illustrates that highly pseudocapacitive Ni(OH)₂ may be more stable when coupled with another oxide rather than directly deposited on metallic current collectors.

As illustrated by the results obtained, the electrode incorporating the hybrid CoO flake-like nanostructures on macroporous nickel foam show a relatively high areal capacitance of approximately 2.3 F cm⁻² because of the porous structure. The CoO nanowalls are quasi-aligned on the nickel surface, which may allow easy access of electrolyte to the entire wall surfaces. Furthermore, the nanowall surfaces may be made more rough and active by further deposition of additional pseudocapacitive nanomaterials. By grafting the porous nanowalls with another pseudocapacitive oxide, the areal capacitance may be further boosted, up to about 11.5 F cm⁻² in embodiments of electrochemically deposited Ni(OH)₂ nanolayers or flake-like nanostructures. Such an ultrahigh areal capacitance of the nanohybrid electrode may be attributed to the much increased surface area caused by its hierarchically porous structure, as well as a synergetic effect between the two oxides. The cost-effective fabrication and excellent electrochemical performance provide great potential for such hybrid 3D nanostructures as an active electrode for electrochemical energy storage applications.

While the method has been described with respect to the fabrication of CoO flake-like nanostructures and Ni(OH)₂ flake-like nanostructures, it should be appreciated that other dissimilar transition metal oxides/hydroxides nanostructures may also be formed using similar methods with suitable modified procedures and steps. As non-limiting examples, combinations of CoO (cobalt oxide) flake-like nanostructures and secondary MnO₂ (manganese oxide) flake-like nanostructures (i.e. CoO@MnO₂), and CoO flake-like nanostructures and secondary Co(OH)₂ (cobalt hydroxide) flake-like nanostructures (i.e. CoO@Co(OH)₂) may be formed.

Nanoflake-Assembled Tubular Array

MnO₂ and NiO are suitable pseudocapacitive materials due to their low cost, high redox activity, environmentally benign nature and natural abundance. The theoretical gravimetric capacitance of MnO₂ and NiO may be as high as 1370 F/g and 2573 F/g, respectively. In various embodiments, these two materials are integrated into a composite pseudocapacitor electrode.

A programmed three-dimensional (3D) interfacial reaction route may be applied to fabricate an array of integrated MnO₂—NiO nanoflake-assembled tubular array, which may be constructed uniformly of a plurality of tubular structures of thin nanoflakes or flake-like nanostructures of MnO₂ and NiO, on a substrate (e.g. a stainless steel substrate). The integrated tubular array architecture is a result of successive deposition of the structural components based on a template and the in-situ removal of the template in the absence of any strong acid or alkali, with ease of structural control and high generality. The MnO₂—NiO tubular array may be an ordered array. The MnO₂—NiO nanoflake-assembled tubular array on stainless steel substrate may be employed to function as a pseudocapacitor electrode.

With the combination of MnO₂ and NiO, a synergistic effect may be obtained in that the firstly-grown MnO₂ flake-assembled array provides a scaffold for the subsequent NiO growth, avoiding or minimising the conventional aggregation, and ensuring sufficient ion diffusion, while the further introduction of NiO may reduce the charge-transfer resistance of MnO₂, leading to fast electron transport within the active MnO₂ and NiO materials. A capacitance per unit area (Cₐ) of about 0.35 F/cm² may be achieved, which is about four orders of magnitude higher than the Cₐ values of carbonaceous materials (10-40 μF cm⁻²), and which is also significantly superior to those of directly-grown pseudocapacitive nanostructure films (0.5-125 mF cm⁻²). The nanoflake-assembled tubular structures may be aligned on a substrate. The nanoflake-assembled tubular structures may be formed directly on the substrate, in contact with a surface of the substrate, so as to provide large electrochemically active area and facile electron transport, leading to good rate capability and long cycle life.

In order to form the array of MnO₂—NiO tubular structures, an array of ZnO nanowires may first be grown on a substrate (e.g. a stainless steel substrate) via a hydrothermal process. The array of ZnO nanowires may be in direct contact with a surface of the substrate. The ZnO nanowires grown may have a diameter of between about 50 nm and about 100 nm and a length of about 5 nm.

The ZnO nanowires may then be coated, at least substantially uniformly, with a carbon layer (e.g. an amorphous carbon layer), by first impregnating the nanowires with a glucose aqueous solution. A subsequent post-annealing process in argon (Ar) gas is performed, subjecting the nanowires, after being impregnated with the glucose aqueous solution, to a carbonization process to form the carbon coating on the ZnO nanowires. However, it should be appreciated that other forms and/or structures of carbon may be employed, for example graphitic carbon such as carbon nanotubes and graphene.

A first interfacial reaction may then be carried out based on the redox reaction between carbon (C) and potassium permanganate (KMnO₄), even at room temperature, according to (3C+4MnO₄⁻+H₂O=4MnO₂+CO₃²⁻+2HCO₃⁻), thereby producing MnO₂ nanostructures on the ZnO nanowires. The reaction results in a MnO₂ flake-like nanostructures on ZnO nanowires core-shell array, where the MnO₂ flake-like nanostructures may be formed branching from the surface or periphery of the ZnO nanowires, covering at least a portion of each ZnO nanowire or substantially the entire surface of each ZnO nanowire. The MnO₂ flake-like nanostructures may branch uniformly from the surface of the ZnO nanowires. The MnO₂ flake-like nanostructures may have a thickness of about 10 nm or less.

Subsequently, a second interfacial reaction may be performed to fabricate the MnO₂—NiO (termed MnO₂@NiO) hybrid tubular array, enabled by the mutually promoted reactions of Ni²⁺ hydrolysis and ZnO etching by H⁺ ions at the nanowire/solution interface. Ni²⁺ may hydrolyze and give rise to proton (H⁺), for example under hydrothermal conditions. As the MnO₂ flake-like nanostructures grown on the ZnO nanowires are interpenetrated and form a highly porous structure, H⁺ may access the nanowire/solution interface, which may initiate the dissolution of the ZnO nanowires. In turn, the consumption of H⁺ by the interfacial ZnO may accelerate the hydrolysis of Ni²⁺. While the concentration of Ni²⁺ may not be at a high level sufficient for homogeneous nucleation, nickel hydroxide may be heterogeneously nucleated at the nanowire/solution interface, which may subsequently stretch out or extend through the voids of the MnO₂ nanoflake networks.

With the continuous dissolution of ZnO in the vicinity of the nanowire/solution interface, an increasing amount of nickel hydroxides is generated due to the accelerated Ni²⁺ hydrolysis, leading, finally, to the formation of MnO₂-nickel hydroxide tubular arrays. An annealing process may be carried out, converting nickel hydroxide to NiO, thereby forming MnO₂—NiO tubular arrays.

The NiO flexible nanoflakes may densely cover the MnO₂ flake-like nanostructures and may be interconnected, crossing the tubular arrays and filling substantially all the void or free spaces.

As the second 3D interfacial reaction occurs at the interface between the pre-grown MnO₂ flake-like nanostructures and the ZnO nanowires, the post-grown NiO flake-like nanostructures share the same “roots” as the MnO₂ flake-like nanostructures, thereby forming a highly integrated hybrid tubular structure, which may adhere robustly to the substrate.

It should be appreciated that the carbon layer-templated growth of MnO₂ is not limited to ZnO nanowire arrays, and therefore nanowires of other materials may be used, including but not limited to nickel oxide (NiO), tin oxide (SnO₂) and cobalt oxide (CoO, Co₃O₄). In addition, other hydrolyzable metal salts apart from nickel, e.g. including non-hydrated metal salts and hydrated metal salts, may be used to form the corresponding metal hydroxide at the nanowire/solution interface. The hydrolyzable metal salts may include a transition metal. The hydrolyzable metal salts may include but not limited to lithium (Li), sodium (Na), calcium (Ca), magnesium (Mg), barium (Ba), titanium (Ti), zirconium (Zr), cesium (Ce), europium (Eu), neodymium (Nd), erbium (Er), ytterbium (Yb), yttrium (Y), vanadium (V), chromium (Cr), manganese (Mn), iron (Fe), cobalt (Co), copper (Cu), silver (Ag), zinc (Zn), cadmium (Cd), aluminium (Al), germanium (Ge), and lead (Pb). Therefore, the combination of the two interfacial reactions as described above may produce a wide spectrum of functional hybrid nanostructure arrays for various applications in catalysis, sensing and energy conversion and storage, etc. In one embodiment, a MnO₂-(α—Fe₂O₃) hybrid tubular array may be formed for use as a lithium-ion battery anode material.

A method for forming an array of MnO₂—NiO nanoflake-assembled tubular array on a stainless steel current collector substrate will now be described by way of the following example, based on a programmed 3D interfacial reaction process. An array of ZnO nanowires may be used as the scaffolds, which is a suitable fabrication template due to its easy availability and dissolution in acid or basic solution. The ZnO nanowires may be formed, for example via a hydrothermal process.

A plurality of ZnO nanowires may be formed directly on a stainless steel substrate and the nanowires subsequently coated with a carbon layer. The fabrication procedures for the carbon-coated ZnO nanowires may be as described in the example above in the context of forming MnO₂ flake-like nanostructures on Co₃O₄ nanowires. The carbon layer may have a thickness of about 6 nm, and coated homogenously on the hydrothermally grown nanowire surface or periphery.

In order to fabricate the array MnO₂—NiO flake-like nanostructures hybrid tubular structures, a 3D interfacial reaction protocol has been custom designed. The carbon-coated ZnO (termed ZnO@C) nanowire array was first immersed into a 0.03 M KMnO₄ aqueous solution and sealed in a Teflon-lined stainless steel autoclave. The sample of carbon-coated ZnO nanowire array was maintained in the autoclave at about 160° C. for about 5 hours. This first process, “Step 1”, enables an interfacial reaction between carbon (C) and KMnO₄ to produce core-shell array of MnO₂ flake-like nanostructures on ZnO nanowires (termed ZnO@MnO₂).

The as-formed core-shell array was then removed from the KMnO₄ aqueous solution and placed into a 20 mL aqueous solution containing 0.5 g Ni(NO₃)₂ and sealed in a Teflon-lined stainless steel autoclave and maintained at about 120° C. for about 12 hours. This second process, “Step 2”, enables an interfacial reaction between nickel ions (Ni³⁺) and the ZnO nanowires. This led to the coating of nickel hydroxide onto the ZnO nanowire surface, with the in-situ dissolution of the ZnO sacrifical template.

An annealing process at about 350° C. in Ar gas was performed for about 2 hours to convert the formed nickel hydroxide into NiO, as well as to improve the mechanical and electrical adhesion between the hybrid nanostructures and the current collector substrate.

For comparison purposes, pure MnO₂ tubular arrays without the second step of NiO growth were also prepared by acid etching (0.1 M hydrochloric acid solution) of the ZnO@MnO₂ core-shell arrays followed by 350° C. annealing.

Microstructure and morphology characterisations were carried out by powder X-ray diffraction (XRD) (Bruker D-8 Avance), transmission electron microscopy (TEM) (JEM-2010FEF, 200 kV), scanning electron microscopy (SEM) (JSM-6700F, 5.0 kV), and Raman spectroscopy (Witech CRM200, 532 nm). Energy dispersive X-ray (EDX) analysis was conducted on an FEI Titan (200 kV) TEM and acquired in scanning TEM (STEM) mode at an equal acquisition time, with a nominal electron beam diameter of about 1 nm for the measurement. X-ray photoelectron spectroscopy (XPS) measurement were performed on a VG ESCALAB 250 spectrometer (Thermo Electron, U.K.) with monochromatic Al Kα (1486.6 eV) irradiation.

Electrochemical measurements were performed on an electrochemical workstation (CHI 760C, CH Instruments Inc., Shanghai) using a three-electrode mode in 1.5 M LiOH aqueous solution within the potential window of approximately −0.2 to 0.6 V. A piece of ˜2 cm² MnO₂—NiO hybrid tubular array on stainless steel foil was directly used as the working electrode. The reference electrode and counter electrode were Ag/AgCl and a platinum plate, respectively. EIS measurements were performed by applying an AC voltage with 5 mV amplitude in a frequency range from 0.01 Hz to 100 kHz at open circuit potential. Prior to the measurements, the array electrode was sealed on all edges, except for the working surface area, with epoxy resin.

The areal capacitance (Cₐ) may be determined from Equation 1 above. The areal energy density, dₑ, may be calculated from the galvanostatic charge-discharge curves according to Equation 3 below.

$${d}_{e} = \frac{{{C}_{a} ( Δ V )}^{2}}{2} . \qquad ( Equation 3 )$$

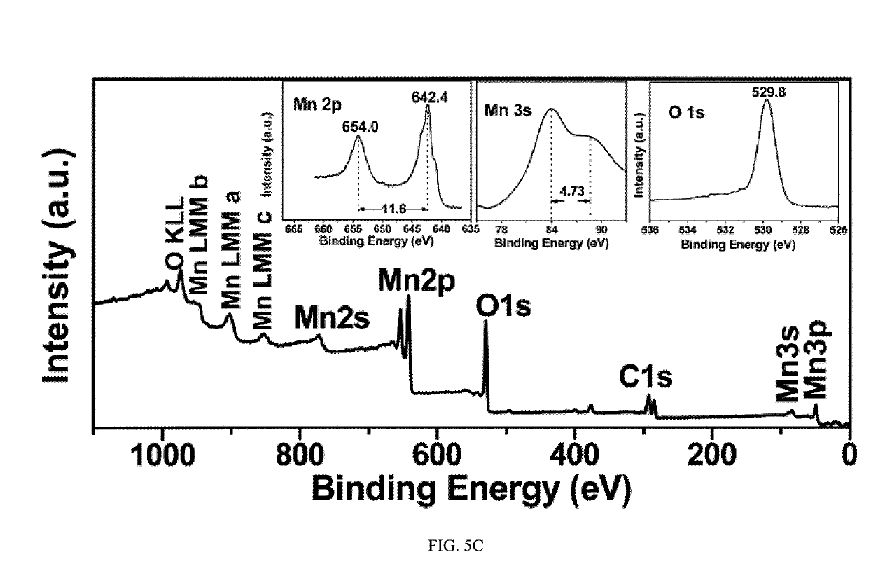

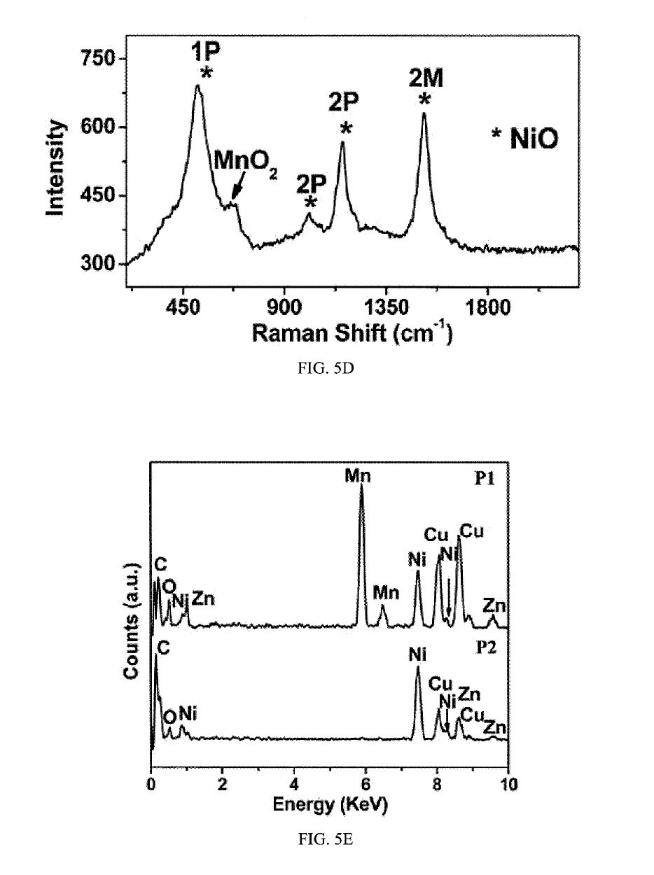

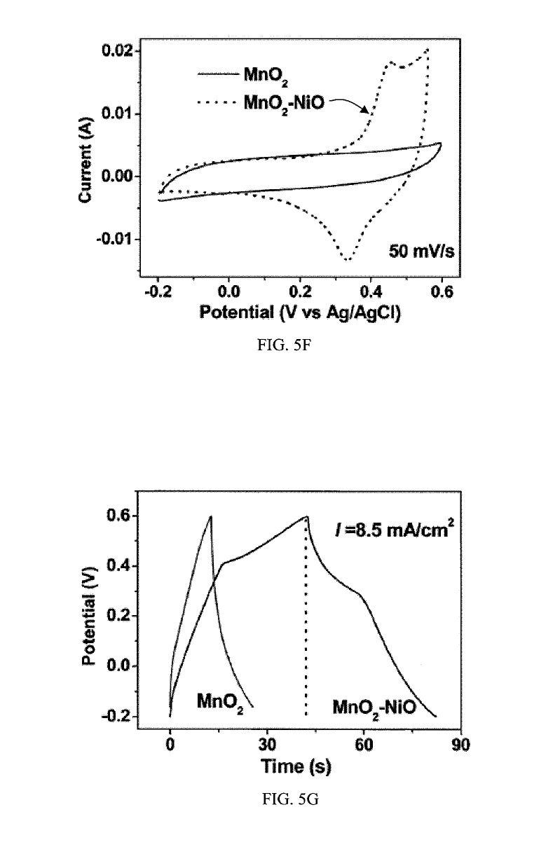

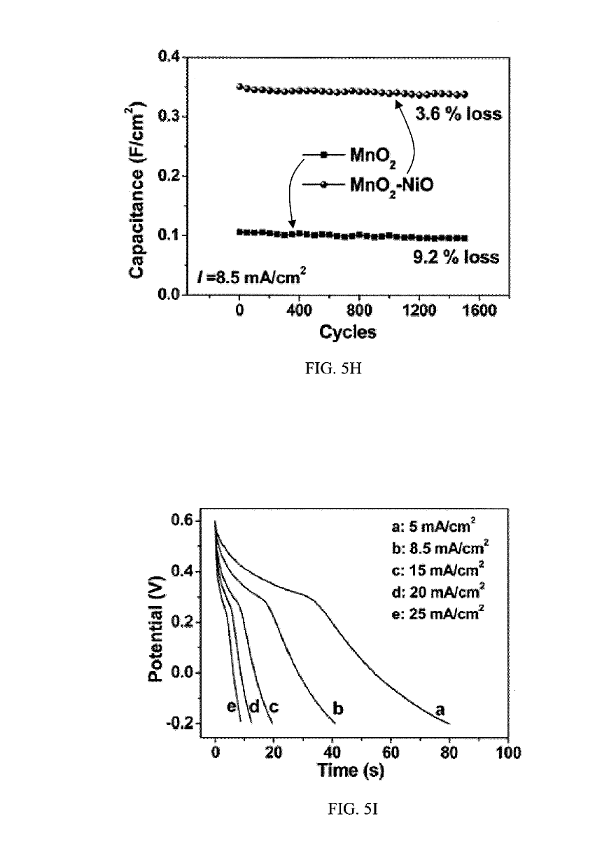

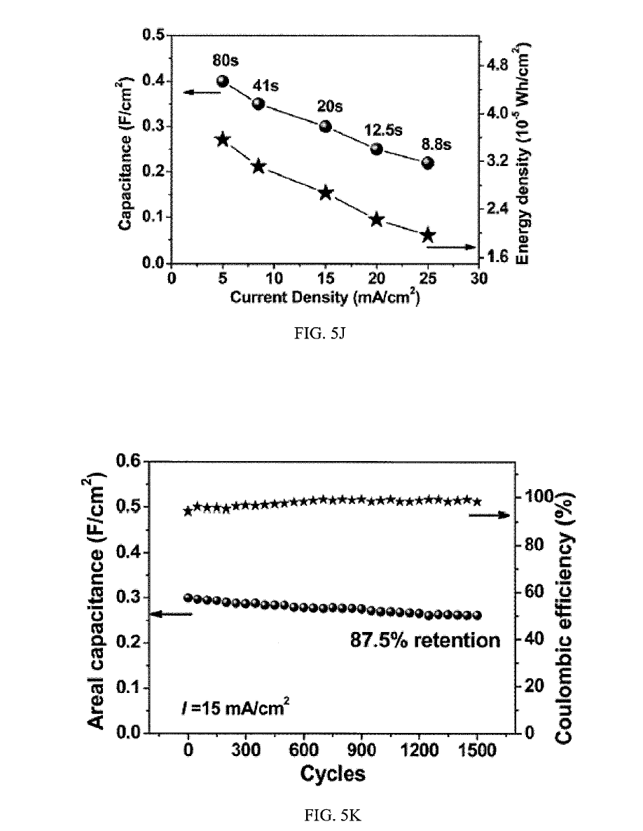

FIG. 5A shows the X-ray diffraction (XRD) pattern of the of the ZnO@MnO₂ hybrid nanostructure array after the first interfacial reaction (Step 1). As mentioned above, carbon (C) may have a redox reaction with potassium permanganate (KMnO₄), even at room temperature, thereby producing MnO₂ materials with a well-defined morphology. Therefore, the carbon layers uniformly coated on the ZnO nanowires serve as a sacrificial template to direct the 3D interfacial reaction. As shown in FIG. 5A, one characteristic peak at about 12.2° from layered birnessite-type MnO2 (JCPDS No. 80-1098) may be observed, in addition to those from ZnO and the current collector substrate.

FIG. 5B shows the Raman spectrum of the of the ZnO@MnO₂ hybrid nanostructure array after the first interfacial reaction (Step 1). As shown in FIG. 5B, except for the peaks at 332 cm⁻¹ and 437 cm⁻¹ of single-crystalline ZnO, the other peaks may be indexed to MnO₂. Raman bands at 655 cm⁻¹ and 577 cm⁻¹ may be recognized as the symmetric stretching vibration (Mn—O) of the MnO₆ groups and the (Mn—O) stretching vibration in the basal plane of the MnO₆ sheet, respectively. No Raman signals of carbon were detected when the recording wavelength was extended up to 2000 cm⁻¹, indicating the substantially complete consumption of carbon.

The obtained array of ZnO@MnO₂ core-shell hybrid nanostructures may be well aligned on the substrate on a large scale. A close-up SEM characterisation (image not shown) shows a uniform coverage of the MnO₂ flake-like nanostructures or nanoflakes on the ZnO nanowire surfaces or periphery. An SEM characterisation of the cross-section of the array (image not shown) show that each ZnO nanowire is substantially entirely and intimately coated with flaky MnO₂.

In order to determine the oxidation state of Mn and confirm the composition of the ZnO@MnO₂ array, XPS of the array was recorded, and the results are shown in FIG. 5C. The Mn 2 p, Mn 3 s and O 1 s spectra are individually shown in the inset of FIG. 5C. The peak located at 529.8 eV is characteristic of the O element in oxide. Mn 2 p_{3/2} peak is centered at 642.4 eV and the Mn 2 p_{1/2} peak at 654.0 eV, with a spin-energy separation of 11.6 eV. The Mn 3 s spectrum shows doublet peaks that result from the parallel spin coupling between the electrons in the 3 s and 3 d orbitals. The splitting width is 4.73 eV, indicating that the Mn oxidation state is 4 on the basis of an approximately linear relationship between the Mn 3 s splitting widths and the Mn oxidation states.

After the formation of the ZnO@MnO₂ core-shell hybrid nanostructure array, the second 3D interfacial reaction was applied to fabricate NiO—MnO₂ hybrid tubular array (termed MnO₂@NiO). SEM and TEM characterisations (images not shown) of a top view of the MnO₂@NiO hybrid nanostructure array after the second interfacial reaction (Step 2) show that NiO flexible nanoflakes densely cover on the MnO₂ nanoflakes and are interconnected crossing the ordered arrays, filling nearly all the void spaces. The underlying MnO₂ flake-like nanostructures may be observable, for example using scanning electron microscopy (image not shown), due to the contrast difference between MnO₂ and NiO. The flake-like morphology of NiO is inherited from nickel hydroxide, which generally grows into two-dimensional nanostructures due to its layered crystal structure.

FIG. 5D shows the Raman spectrum of the MnO₂@NiO hybrid nanostructure array after the second interfacial reaction (Step 2). The Raman spectrum shows that in addition to the peak at 655 cm⁻¹ from MnO₂, the other peaks may be indexed to pure NiO. The first three bands have vibrational origin and correspond to one-phonon (1P) transverse optical (TO) and longitudinal optical (LO) modes (at ˜515 cm⁻¹), two-phonon (2P) TO+LO (at ˜1008 cm⁻¹) and 2LO (at ˜1153 cm⁻¹) modes. The last strong band at 1514 cm⁻¹ is due to a two-magnon (2M) scattering. The absence of ZnO Raman peaks shows the substantial dissolution of the ZnO single-crystal nanowires.

The structure and morphology evolution of the hybrid array was further characterised by TEM (images not shown), which show a MnO₂ nanoflake layer of ˜50 nm thickness was deposited tightly on the ZnO nanowires after the carbon-templated interfacial reaction. It was observed that some ZnO nanowires have already been etched at this growth stage, which may be due to the presence of HCO₃⁻ in the solution (for example produced from the reaction between carbon and MnO₄⁻). Completely tubular structure, with a hollow core, was observed after the second interfacial growth. Even with two components integrated, the structure remains highly uniform with straight and clear tube walls.

TEM characterisations (images not shown) of the tube surface show that the NiO nanoflakes are porous, with pore sizes of 2-5 nm, but structurally continuous. The pores are generated because of the loss of water from the structure during the thermal decomposition of nickel hydroxide. The flake thickness was determined to be less than 10 nm from the cross sections of the NiO nanoflakes.

A darkfield STEM image (not shown) of two tubular structures was obtained for EDX analysis. Two different positions (P1: inner flakes; P2: outer flakes) were detected and the results are shown in FIG. 5E. The carbon and Cu signals are from the carbon-supported Cu grid for holding the sample. While the inner nanoflakes (P1) contain both Ni and Mn elements, no signal corresponding to Mn is observable for the outer flakes, further providing support that the growth of nickel hydroxide started from the MnO₂/ZnO interface. The presence of Zn traces may be ascribed to the residual Zn species, but which does not substantially affect the electrochemical performance of the hybrid nanostructure.

In order to determine the electrochemical capacitive performance of the MnO₂@NiO tubular array, cyclic voltammogram (CV) was recorded at the scan rate of 50 mV s⁻¹, and the results are shown in FIG. 5F. For comparison purposes, the CV of pristine MnO₂ tubular array is also shown in FIG. 5F. The CV measurements were conducted in a three-electrode system using saturated Ag/AgCl as the reference electrode and platinum foil as the counter-electrode. For pure MnO₂, the CV curve exhibits rectangular-like shape without observable redox peaks, and the capacitive behavior of MnO₂ may be ascribed to surface cation (Li⁺) adsorption from electrolyte and possible intercalation/deintercalation of Li⁺.

With the NiO integrated, while there is no observable CV shape change within the potential window of −0.2˜0.2 V, a pair of redox peaks at 0.33 V and 0.46 V may be observed, which may be due to the reversible reactions of Ni²⁺/Ni³⁺ associated with anions OH⁻: NiO+OH⁻+ [symbol] NiOOH+e⁻. As can be observed from FIG. 5F, the CV integrated area of the hybrid MnO₂@NiO array is larger than that of the pristine MnO₂ array, which may lead to an increase in the pseudocapacitance.

The areal capacitances (Cₐ) of both the MnO₂@NiO and MnO₂ tubular arrays were calculated from charge-discharge profiles. FIG. 5G shows a plot of charge/discharge curves of the first cycle in the potential range of −0.2˜0.6V at a current density of 8.5 mA cm⁻² for the MnO₂@NiO and MnO₂ tubular arrays. The voltage plateaus for the MnO₂@NiO array correspond with the peaks observed in the CV curve of FIG. 5F. The charging/discharging times are nearly the same, indicating superior reversibility of the redox reaction. The Cₐ for the MnO₂@NiO array was estimated to be 0.35 F cm⁻², which is nearly 3.5 times compared to that of the pristine MnO₂ tubular array (0.101 F cm⁻²). The Cₐ of 0.35 F cm⁻² is also 4 orders of magnitude higher than those of conventional carbonaceous materials (10-40 μF cm⁻²) and much greater than directly-grown pseudocapacitive nanostructure films, for example TiO₂ nanotube film (0.538-0.911 mF cm⁻²).

The high Cₐ value for the hybrid MnO₂@NiO nanostructure array results from the effective integration of nanoflake-shaped MnO₂ and NiO into an ordered and tubular structure directly on a current collector substrate. As the constituent high-capacitance pseudocapacitive materials grow densely on the entire electrode surface without electrochemically-inert additives, this not only saves the active spaces but may also offer greatly improved electron transfer pathways. Furthermore, the porous nature of NiO nanoflakes and the interspacing voids formed by interconnected flakes as well as the tubular structures may allow an effective contact between the electrolyte (Li⁺, OH⁻) and the two active MnO₂ and NiO materials, which may allow adequate ion supply for redox reactions.

In order to determine the fundamental behavior of supercapacitor electrodes, EIS analysis was performed and the results (not shown) show that more facile charge transfer may be achieved by integrating NiO nanoflakes into the tubular array architecture. The hybrid MnO₂@NiO array exhibit a reduced Faraday resistance, rendered by the material combination and the hierarchical structure, which leads to an enhanced electrochemical reaction, contributing to the observed large Cₐ value of the hybrid MnO₂@NiO array.

In addition to the much higher Cₐ, the hybrid MnO₂@NiO nanostructure array also demonstrates superior cycling performance compared to pristine MnO₂ array. FIG. 5H shows a plot of cycling performance of the MnO₂@NiO and MnO₂ tubular arrays at a current density of 8.5 mA cm⁻², illustrating the respective discharge capacitances as a function of cycle number. As shown in FIG. 5H, the hybrid array exhibits excellent electrochemical stability with only 3.6% deterioration of the initial capacitance after 1500 cycles. The pristine MnO2 array, however, has 9.2% capacitance loss after cycling. While not wishing to be bound, it is believed that the intimate “root contact” of the NiO flakes with the MnO₂ flakes, and the networking of MnO₂ by filling in the array voids with flexible interpenetrated NiO flakes, may help to maintain the structural integrity and mechanical adhesion with the current collector, thus improving long-term electrochemical cycling.

The hybrid MnO₂@NiO array was examined at different current densities and the galvanostatic discharge curves obtained are as shown in FIG. 5I. FIG. 5J shows a plot of rate capability and energy density as a function of current density for the MnO₂@NiO tubular array, illustrating the relationship between the Cₐ value and the areal energy density, dₑ, with the current density. The times required for full discharging at each current density are indicated in FIG. 5J.

As the reversible redox reaction is a highly diffusion-controlled process, the capacitance decreases at fast charge-discharge rate. The Cₐ at current densities of 5 mA cm⁻², 8.5 mA cm⁻², 15 mA cm⁻², 20 mA cm⁻², and 25 mA cm⁻² is determined to be ˜0.4 F cm⁻², 0.35 F cm⁻², 0.3 F cm⁻², 0.25 F cm⁻², and 0.22 F cm⁻², respectively. At the current density as high as 25 mA cm⁻² (discharge within 8.8 seconds), 55% of the capacitance at 5 mA cm⁻² may be retained, which is much higher than conventional carbonaceous materials and pseudocapacitive nanostructure arrays. The electrochemical performance of pure MnO₂ tubular array was examined at high current densities, but its capacitance decreased was observed to decrease dramatically for current densities larger than 10 mA cm⁻² (results not shown). The superior rate capability of hybrid MnO₂@NiO tubular array may be attributed to its substantially reduced charge-transfer resistance (ensuring fast redox kinetics).

As further shown in FIG. 5J, the hybrid tubular array exhibits energy density in the order of magnitude of 10⁻⁵ Wh cm⁻². The dₑ values at 5 mA cm⁻² and 25 mA cm⁻² are ˜3.56×10⁻⁵ Wh cm⁻² and 1.96×10⁻⁵ Wh cm⁻², respectively, which are several times that of conventional carbon fiber and carbon nanotube-based supercapacitors.

In order to examine the electrochemical performance of the hybrid array at high rates, the cycling performance at a much larger current density of 15 mA cm⁻² (which is 5-10 times that of commonly used value) was determined and the result are shown in FIG. 5K. The coulombic efficiency as a function of cycle number is also shown.

After 1500 cycles, the tubular hybrid array may retain 87.5% of the initial capacitance with >96% Coulombic efficiency from the 10th cycle, with a final Coulombic efficiency of ˜99%. FIG. 5L shows a plot of the charge/discharge curves of the last 20 cycles for the MnO₂@NiO tubular array, which show substantially similar shapes, indicating excellent long-term cyclability of the hybrid array electrode, even under fast charge-discharge conditions.

As illustrated by the results obtained, the electrode incorporating the hybrid MnO₂@NiO tubular array show much higher areal capacitance than conventional carbonaceous materials (approximately four orders of magnitude higher) and directly-grown pseudocapacitive nanostructure films, while also exhibiting good cyclability and rate capability. Both the MnO₂ and NiO flake-like nanostructures contribute to the charge storage, and the highly porous structure allows easy penetration of the electrolyte.

Therefore, integrated tubular arrays incorporating two or more high capacitance pseudocapacitive materials, for example in the form of flake-like nanostructures, may be suitable in supercapacitor applications, e.g in thin-film supercapacitors and other kinds of electrochemical devices.

In the context of various embodiments, it should be appreciated that materials that are described in the context of an embodiment may correspondingly be applicable to the other embodiments. In addition, it should be appreciated that various embodiments may be combined.

In the context of various embodiments, further enhancement of electrochemical performances, for example the rate capability, may be achieved by incorporating electron-transporting materials (e.g. conducting polymers) into the nanostructure arrays. The conducting polymers may be incorporated by means of electro-polymerization or chemical polymerization, both methods beginning from the monomer of the polymer and the polymerization process may be easily controlled.

In the context of various embodiments, electrodes incorporating the array of nanostructures or integrated hybrid nanostructures of various embodiments may be employed in a pseudocapacitor cell. A carbon-based (e.g. active carbon, carbon nanotubes, or graphene, etc.) counter electrode may be incorporated into the pseudocapacitor cell.

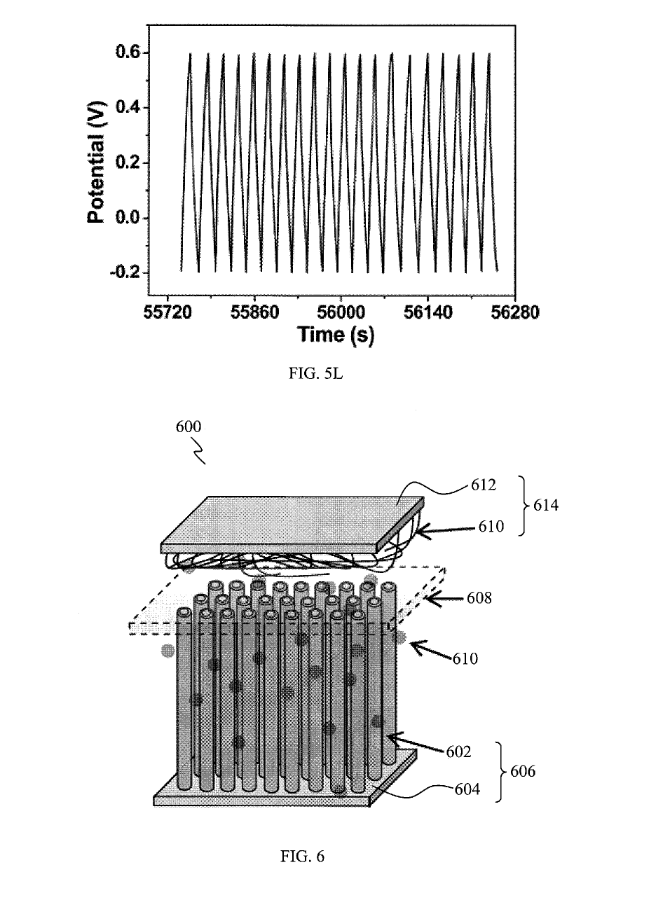

FIG. 6 shows a schematic perspective view of a pseudocapacitor cell 600, according to various embodiments. The pseudocapacitor cell may be constructed by first forming the array of nanostructures as described above in the context of various embodiments. For illustration purposes and as a non-limiting example, in one embodiment, the array of nanostructures may be an integrated hybrid core-shell array 602 (e.g. an array of core-shell nanostructures having MnO₂ flake-like nanostructures on Co₃O₄ nanowires, Co₃O₄@MnO₂) formed on a substrate (e.g. stainless steel) 604. The as-grown array of hybrid nanostructures 602 on the substrate 604 may be employed as a cathode 606, and may be covered with a microporous polypropylene membrane 608 saturated with an electrolyte (e.g. LiOH) 610. A carbon material-based electrode, e.g. having carbon nanowires 610 grown on a substrate 612, as an anode 614 may be incorporated into the cell 600. Alternatively, the carbon materials may be treated into a uniform film on a current collector substrate by means of a spin/spray coating of the inks on the substrate. The two-electrode full pseudocapacitor cell may then be sealed with a polymer resin. An electrolyte solution may also be provided within the pseudocapacitor cell.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. Hybrid nanostructure comprising at least two pseudocapacitative materials arranged in an elongate core-shell arrangement, wherein the core is an elongate nanostructure comprising or consisting of the first pseudocapacitative material and the shell is a plurality of flake- or sheet-like nanostructures attached to the core structure and comprising or consisting of the second pseudocapacitative material.

2. Hybrid nanostructure of claim 1, wherein the elongate nanostructure is a nanowire.

3. Hybrid nanostructure of claim 1, wherein the first pseudocapacitative material comprises or consists of a transition metal oxide or a transition metal hydroxide.

4. Hybrid nanostructure of claim 1, wherein the first pseudocapacitative material is selected from the group consisting of cobalt oxide, nickel oxide, zinc oxide, tin oxide and any combination thereof.

5. Hybrid nanostructure of claim 1, wherein the second pseudocapacitative material comprises or consists of a transition metal oxide or a transition metal hydroxide.

6. Hybrid nanostructure of claim 1, wherein the second pseudocapacitative material comprises or consists of manganese oxide or cobalt oxide or nickel oxide or nickel hydroxidenitrate.

7. Hybrid nanostructure of claim 1, wherein the elongate nanostructure is porous.

8. Hybrid nanostructure of claim 1, wherein the elongate nanostructure has a diameter of between about 50 nm and about 100 nm.

9. Hybrid nanostructure of claim 1, wherein the elongate nanostructure has a length of between about 1 μm and about 10 μm.

10. Hybrid nanostructure of claim 1, wherein each flake- or sheet-like nanostructure is porous.

11. Hybrid nanostructure of claim 10, wherein each flake- or sheet-like nanostructure each flake-like nanostructure has pores of a diameter of between about 10 nm and about 100 nm.

12. Hybrid nanostructure of claim 1, wherein each flake- or sheet-like nanostructure has a thickness of between about 1 nm and about 10 nm.

13. Hybrid nanostructure of claim 1, wherein each flake- or sheet-like nanostructure extends between about 10 nm and about 100 nm from a surface of the elongate nanostructure.

14. Hybrid nanostructure of claim 1, wherein the plurality of flake- or sheet-like nanostructures are cross-linked.

15. Hybrid nanostructure of claim 1, wherein at least a portion of each flake- or sheet-like nanostructure is spaced apart relative to an adjacent flake- or sheet-like nanostructure.

16. An electrode comprising:
a substrate; and
a plurality of spaced apart hybrid nanostructures according to claim 1 extending from a surface of the substrate.

17. The electrode of claim 16, wherein the plurality of spaced apart hybrid nanostructures are arranged in direct contact with the surface of the substrate.

18. The electrode of claim 16, wherein the surface of the substrate comprises a porous surface.

19. A method for forming a hybrid nanostructure according to claim 1, the method comprising:
providing a substrate;
forming a plurality of spaced apart elongate nanostructures comprising or consisting of the first pseudocapacitative material extending from a surface of the substrate; and
forming a plurality of flake- or sheet-like nanostructures comprising or consisting of the second pseudocapacitative material on the surface of each elongate nanostructure.

20. The method of claim 19, wherein the step of forming the plurality of flake- or sheet-like nanostructures comprises the step of forming an interfacial reactive template layer on the surface of each elongate nanostructure and reacting the template layer with a precursor of the second pseudocapacitative material to form the plurality of flake- or sheet-like nanostructures on the surface of each elongate nanostructure.

21. The method of claim 20, wherein the interfacial reactive template layer is a coating on the surface of each elongate nanostructure, the coating having a thickness of between about 2 nm and about 10 nm.

22. The method of claim 20, wherein forming the interfacial reactive template layer comprises:
immersing at least a portion of each elongate nanostructure in an aqueous glucose solution; and
thereafter subjecting the elongate nanostructure to a carbonization process.

23. The method of claim 22, wherein the second pseudocapacitative material comprises or consists of manganese oxide.

24. The method of claim 19, wherein the plurality of elongate nanostructures are formed by means of a hydrothermal process or an electrodeposition process or a chemical vapour deposition process.

25. An electrode comprising:
a substrate; and
a plurality of flake- or sheet-like nanostructures comprising or consisting of at least one pseudocapacitative material extending from a surface of the substrate.

26. The electrode of claim 25, wherein the pseudocapacitative material comprises or consists of a transition metal oxide or a transition metal hydroxide.

27. The electrode of claim 25, wherein the pseudocapacitative material comprises or consists of cobalt oxide or nickel oxide.

28. The electrode of claim 25, wherein the plurality of flake- or sheet-like nanostructures are arranged in direct contact with the surface of the substrate.

29. The electrode of claim 25, wherein the surface of the substrate comprises a porous surface.

30. The electrode of claim 25, wherein each flake- or sheet-like nanostructure is porous.

31. The electrode of claim 30, wherein each flake- or sheet-like nanostructure has pores of a diameter of between about 10 nm and about 100 nm.

32. The electrode of claim 25, wherein each flake- or sheet-like nanostructure has a thickness of between about 1 nm and about 10 nm.

33. The electrode of claim 25, wherein each flake- or sheet-like nanostructure extends between about 10 nm and about 100 nm from the surface of the substrate.

34. The electrode of claim 25, wherein the plurality of flake- or sheet-like nanostructures are cross-linked.

35. The electrode of claim 25, wherein at least a portion of each flake- or sheet-like nanostructure is spaced apart relative to an adjacent flake- or sheet-like nanostructure.

36. The electrode of claim 35, wherein the spacing is at least about 50 nm.

37. The electrode of claim 25, wherein the substrate is a metal substrate.

38. The electrode of claim 25, wherein each flake- or sheet-like nanostructure further comprises a second pseudocapacitative material.

39. The electrode of claim 38, wherein the second pseudocapacitative material comprises or consists of a transition metal oxide or a transition metal hydroxide.

40. The electrode of claim 38, wherein the second pseudocapacitative material comprises or consists of manganese oxide or nickel hydroxide or cobalt hydroxide.

41. The electrode of claim 38, wherein each flake- or sheet-like nanostructure comprises a coating comprising or consisting of the second pseudocapacitative material on a surface of each flake-like nanostructure.

42. A method for forming an electrode according to claim 25, the method comprising:
providing a substrate; and
forming a plurality of flake- or sheet-like nanostructures comprising or consisting of a pseudocapacitative material extending from a surface of the substrate.

43. The method as claimed in claim 42, wherein the plurality of flake- or sheet-like nanostructures are formed by means of a hydrothermal process.

44. The method as claimed in claim 42, further comprising forming a coating comprising or consisting of a second pseudocapacitative material on a surface of each flake- or sheet-like nanostructure.

45. The method as claimed in claim 44, wherein the coating is formed by means of an electrodeposition process.
